(19) United States
(12) Patent Application Publication
(10) Pub. No.: US 2014/0036119 A1
(43) Pub. Date: Feb. 6, 2014

(54) SOLID-STATE IMAGING DEVICE

(71) Applicant: Panasonic Corporation, Osaka (JP)

(72) Inventors: Kenichi SHIMOMURA, Hyogo (JP); Hiroshi FUJINAKA, Osaka (JP); Hirohisa OHTSUKI, Toyama (JP)

(73) Assignee: PANASONIC CORPORATION, Osaka (JP)

(21) Appl. No.: 14/049,884

(22) Filed: Oct. 9, 2013

Related U.S. Application Data
(63) Continuation of application No. PCT/JP2012/002652, filed on Apr. 17, 2012.

(30) Foreign Application Priority Data
Apr. 22, 2011 (JP) 2011-096638

(51) Int. Cl. H04N 5/235

(52) U.S. Cl. CPC H04N 5/2355
USPC 348/294

(57) ABSTRACT

The solid-state imaging device according to the present invention includes a valid pixel area, a horizontal OB area, and a peripheral circuit area. The valid pixel area includes valid pixel cells from each of which an image signal corresponding to incident light is outputted. The horizontal OB area includes light-blocking pixel cells from each of which a black level signal not depending on the incident light. The peripheral circuit area includes a peripheral circuit. When (i) the valid pixel area has N line layers, (ii) each of the horizontal OB area and the peripheral circuit area has M line layers, and (iii) N<M, an (N+2)th line layer blocks light incident on the horizontal OB area, and an interlayer insulating film is filled between the (N+2)th line layer and the N-th line layer in the horizontal OB area.

### CROSS REFERENCE TO RELATED APPLICATION(S)

This is a continuation application of PCT International Patent Application No. PCT/JP2012/002652 filed on Apr. 17, 2012, designating the United States of America, which is based on and claims priority of Japanese Patent Application No. 2011-096638 filed on Apr. 22, 2011. The entire disclosures of the above-identified applications, including the specifications, drawings and claims are incorporated herein by reference in their entirety.

### FIELD

The present invention relates to solid-state imaging devices, and more particularly to a Metal-Oxide-Semiconductor (MOS) solid-state imaging device such as a Complementary Metal-Oxide-Semiconductor (CMOS) image sensor.

### BACKGROUND

In recent years, with the increase of the number of pixels in mobile telephones and handheld digital cameras, an imaging device having more than ten million pixels is embedded in such devices. On the other hand, the consuming market prefers downsizing and demands thinner devices. Therefore, increase of an optical size of an imaging device (a size of an entire pixel array) is not welcomed. As a result, it has been required to reduce an area per pixel inversely proportional to the increase of pixels for a long time.

If an area per pixel is reduced, an area for a photodiode is also reduced and metal line layers block a light path. As a result, a sensitivity is deteriorated. In addition, the reduction of an area per pixel causes stray light and thereby increases color mixture. In order to prevent the above problems, various techniques have been developed. For example, light is collected by an on-chip lens, a transistor and a control signal are shared by a plurality of pixels to increase an area for a photodiode, a layout is modified to reduce the number of line layers or expand line openings, a thickness of each of line layers and interlayer films is decreased, and an optical waveguide path is provided.

FIG. 12 is a schematic diagram showing a structure of a conventional solid-state imaging device disclosed in Patent Literature 1. FIG. 13 is a cross-sectional view of a part of the conventional solid-state imaging device taken along line A-A of FIG. 12. The conventional solid-state imaging device 800 shown in FIG. 12 includes a sensor region 820 and peripheral circuit regions 830. The sensor region 820 includes: a valid pixel region 821; a light-blocking pixel region (hereinafter, referred to as an “OPB region”) 823 that outputs reference signals of black levels; and an invalid pixel region 822.

With reference to the cross-sectional view of FIG. 13, line layers 1MT, 2MT, and the like, along each of which photodiodes (hereinafter, referred to as “PDs”), metal films 844, and metal films 845 are arranged, have the same structures with a periodicity from the valid pixel region 821 to the OPB region 823. Furthermore, a passivation film 851, a color filter 852, and an on-chip lens 853 are arranged along a path through which light is incident on the valid pixel region 821. The structure is arranged periodically to the middle of the invalid pixel region 822. Moreover, in the OPB region 823, line layers 3MT and 4MT are provided over PDs to block light. As a result, reference signals of black level can be outputted.

### CITATION LIST

### Patent Literature

[Patent Literature 1] Japanese Unexamined Patent Application Publication No. 2010-267675

### SUMMARY

### Technical Problems

With the above-described advance of technologies in pixel structure, a speed has been increased as one of recent developments. In particular, for imaging devices having a video obtaining function, the number of pixels in obtaining video is considerably increased. Sometimes, a frame rate of more than 60 frames per second is demanded. There is a need for dramatically increase of a speed in reading pixel signals.

Here, a time duration of reading from a solid-state imaging device is analyzed. When N represents the number of scanning lines (rows) required to output image of one frame in a predetermined reading mode, T_{L} represents a reading cycle from a k-th row to a (k+1)th row, in other words, a row cycle time duration, and Tᵥ represents a reading cycle from a certain frame to a next frame, in other words, a frame cycle time duration, it is necessary to satisfy a relationship expressed by following Mathematical Formula 1.

T_{L}×N<T_{V} (Mathematical Formula 1)

In general, it is necessary for video to keep a certain frame rate. Therefore, a frame rate such as 30 fps, 60 fps, or higher is defined for each reading mode. If a frame rate is 60 fps, T_{V} is 16.6 ms. For the sake of simplicity of the description, it is assumed that an aspect ratio of twelve million pixels is 4:3, in other words, a pixel array has 3000 rows and 4000 columns. Under the assumption, following Mathematical Formula 2 is obtained from Mathematical Formula 1.

T_{L}=T_{V}÷N=16.6 ms÷3000=5.5 us (Mathematical Formula 2)

This is a maximum row cycle time duration to achieve a frame rate of 60 fps by twelve million pixels, under assumption that there is any other constraint, for example, no blanking time duration in pixel accessing. In addition, it is also considerable that the row cycle time duration will be further shortened to meet demands for frame rate improvement and pixel increase preference. It is therefore necessary to suppress a pixel reading cycle per row to, for example, roughly 3 μs. The above-described speed increase requires a shorter, almost minimum, time margin of a pixel reading sequence.

However, the measures for achieving image having correct black reference to address the pixel area reduction are disadvantageous for the speed increase in a pixel reading cycle. More specifically, the measures, such as thinner line layers, thinner interlayer films, and reduction of the number of line layers in a pixel unit, are disadvantageous to increase a speed of a pixel reading cycle.

In order to solve the above-described conventional problems, an object of the present invention is to provide a solid-state imaging device capable of obtaining, at a high speed, image with correct black reference and with a small amount of noises even on the conditions where a light amount is small.

### Solution to Problem

In accordance with an aspect of the present invention for solving the above problems, there is provided a solid-state imaging device in which a plurality of pixel cells are arrayed in a matrix in or on a semiconductor substrate, the pixel cells each including a photoelectric conversion element and a transistor connected to the photoelectric conversion element, the solid-state imaging device comprising: a valid pixel area including valid pixel cells from each of which an image signal corresponding to incident light is outputted, the valid pixel cells being included in the pixel cells; a light-blocking pixel area peripheral to the valid pixel area and including light-blocking pixel cells from each of which a black level signal independent of the incident light that is blocked is outputted, the light-blocking pixel cells being included in the pixel cells; and a peripheral circuit area peripheral to the valid pixel area and the light-blocking pixel area, the peripheral circuit area including a peripheral circuit that drives the pixel cells and performs signal processing, wherein, when (i) the valid pixel area has N line layers (where N is a natural number), (ii) the light-blocking pixel area has M line layers (where M is a natural number), (iii) the peripheral circuit area has L line layers (where L is a natural number), (iv) the valid pixel area, the light-blocking pixel area, and the peripheral circuit area share line layers up to an N-th line layer from a surface of the semiconductor substrate, and (v) N<M≦L, a light-blocking line layer among the line layers blocks light incident on photoelectric conversion elements in the light-blocking pixel area, and an interlayer insulating film is filled between the light-blocking line layer and the N-th line layer, the light-blocking line layer being one of an (N+2)th line layer and a line layer higher than the (N+2)th line layer.

### Advantageous Effects

The solid-state imaging device according to the present invention is capable of reducing parasitic capacitance specific to a light-blocking pixel area. As a result, the solid-state imaging device can obtain, at a high speed, image with correct black reference and with a small amount of noises even on the conditions where a light amount is small.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 is a schematic diagram showing a structure of a solid-state imaging device according to Embodiment 1.

FIG. 2 is a schematic diagram showing a structure of a pixel array according to Embodiment 1.

FIG. 3A is a circuit diagram of showing a structure of a certain pixel circuit in a valid pixel area according to Embodiment 1.

FIG. 3B is a time chart for explaining reading performed in a pixel circuit in the valid pixel area according to Embodiment 1.

FIG. 4A is a planar layout diagram showing a silicon substrate including a diffusion layer, polysilicon, and contacts according to Embodiment 1.

FIG. 4B is a planar layout diagram showing: the silicon substrate; a first line layer above the silicon substrate; and vias connecting the first line layer to a line layer immediately above the first layer, according to Embodiment 1.

FIG. 4C is a planar layout diagram showing: the silicon substrate; the first line layer and the vias all of which are above the silicon substrate; and a second line layer and a fourth line layer according to Embodiment 1.

FIG. 5A is a cross-sectional view of pixels included in a conventional solid-state imaging device.

FIG. 5B is a cross-sectional view of pixels included in the solid-state imaging device according to Embodiment 1.

FIG. 6A is a circuit diagram of light-blocking pixels where a parasitic capacitance component increased by a layout difference between a light-blocking pixel and a valid pixel is shown, according to Embodiment 1.

FIG. 6B is a time chart in which a reading waveform of a valid pixel is compared to a reading waveform of a light-blocking pixel in a conventional solid-state imaging device.

FIG. 6C is a time chart in which a reading waveform of a valid pixel is compared to a reading waveform of a light-blocking pixel in the solid-state imaging device according to Embodiment 1.

FIG. 7A is a circuit diagram showing a structure of a certain pixel circuit in a valid pixel area according to Embodiment 2.

FIG. 7B is a time chart for explaining reading performed in a pixel circuit in the valid pixel area according to Embodiment 2.

FIG. 8A is a planar layout diagram showing a silicon substrate including a diffusion layer, polysilicon, and contacts according to Embodiment 2.

FIG. 8B is a planar layout diagram showing: the silicon substrate; a first line layer above the silicon substrate; and vias connecting the first line layer to a line layer immediately above the first layer, according to Embodiment 2.

FIG. 8C is a planar layout diagram showing: the silicon substrate; the first line layer and the vias all of which are above the silicon substrate; and a second line layer and a fourth line layer according to Embodiment 2.

FIG. 9A is a cross-sectional view of pixels included in a conventional solid-state imaging device.

FIG. 9B is a cross-sectional view of pixels included in the solid-state imaging device according to Embodiment 2.

FIG. 10A is a circuit diagram of light-blocking pixels where a parasitic capacitance component increased by a layout difference between a light-blocking pixel and a valid pixel is shown, according to Embodiment 2.

FIG. 10B is a time chart in which a reading waveform of a valid pixel is compared to a reading waveform of a light-blocking pixel in a conventional solid-state imaging device.

FIG. 10C is a time chart in which a reading waveform of a valid pixel is compared to a reading waveform of a light-blocking pixel in the solid-state imaging device according to Embodiment 2.

FIG. 11 is a cross-sectional view of a boundary part between a valid pixel area and a light-blocking pixel area in a solid-state imaging device according to a variation of the embodiments.

FIG. 12 is a schematic diagram showing a structure of the solid-state imaging device disclosed in Patent Literature 1.

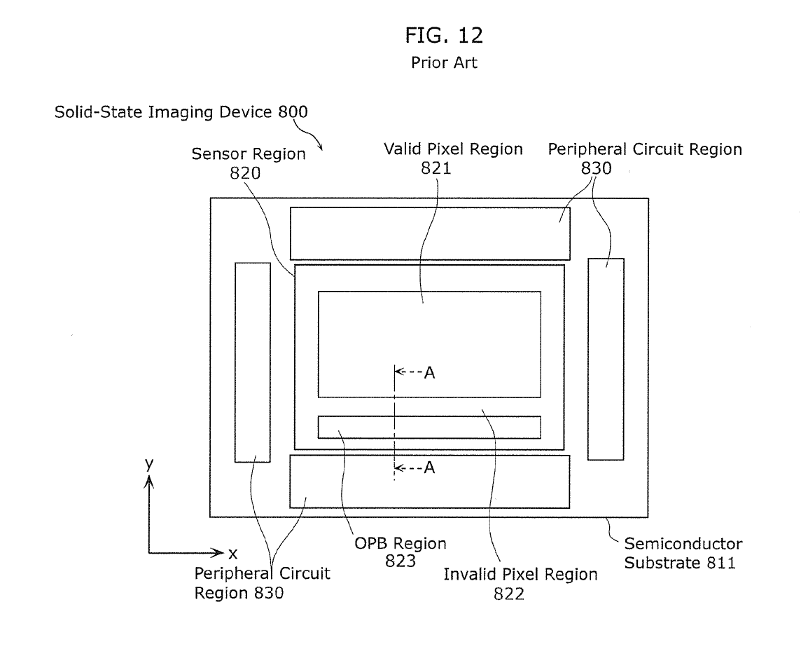

FIG. 13 is a cross-sectional view of the solid-state imaging device taken along line A-A of FIG. 12.

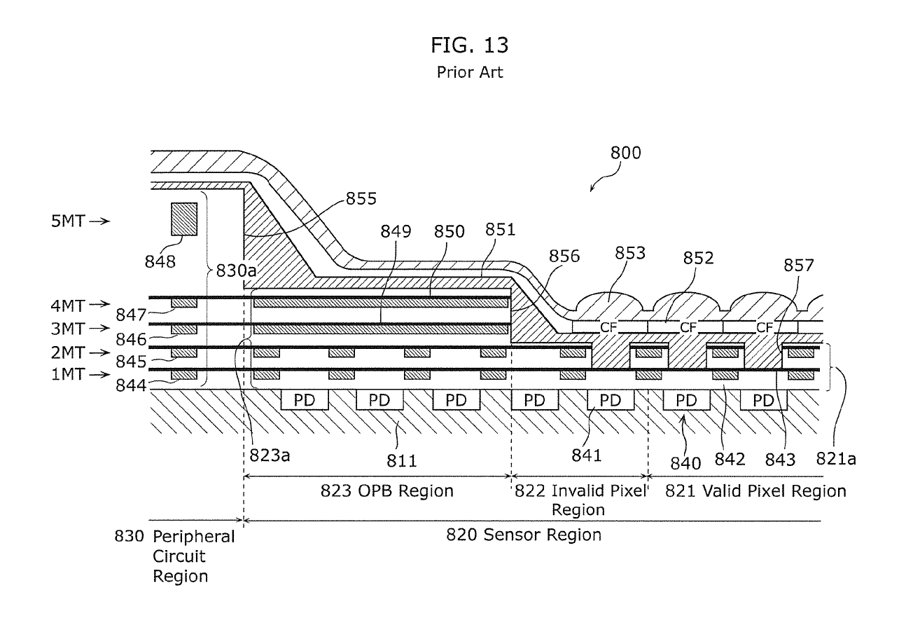

FIG. 14 is a cross-sectional view for explaining problems in the conventional solid-state imaging device disclosed in Patent Literature 1.

### DESCRIPTION OF EMBODIMENTS

### Observation Based on which Present Invention has been Conceived

The following describes results of detailed analysis conducted by the inventors on problems occurred in increasing a speed of a pixel reading cycle.

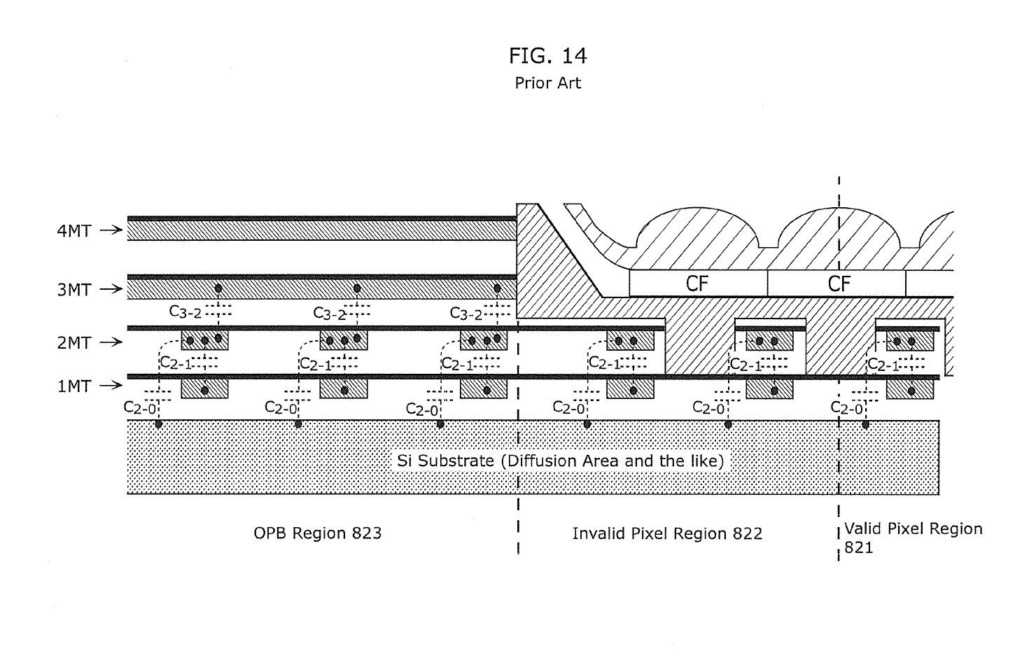

FIG. 14 is a cross-sectional view for explaining the problems in the conventional solid-state imaging device disclosed in Patent Literature 1. Focusing attention to parasitic capacitances in the line layer 2MT in the valid pixel region 821, the invalid pixel region 822, and the OPB region 823, it is seen that (a) parasitic capacitances C₂_{_{—}}₀ in respective pixels between the line layer 2MT and the silicon substrate (including an electrical node on the surface of the silicon substrate, such as a photodiode and a gate of an inter-pixel transistor) have the same value in respective pixels in the valid pixel region 821, the invalid pixel region 822, and the OPB region 823, and (b) parasitic capacitances C₂_{_{—}}₁ in respective pixels between the line layer 2MT and the line layer 1MT have the same value in respective pixels in the valid pixel region 821, the invalid pixel region 822, and the OPB region 823.

On the other hand, parasitic capacitances C₃_{_{—}}₂ between the line layer 2MT and the line layer 3MT occur only in pixels in the OPB region 823.

As described above, as a thickness of an interlayer film is decreased to reduce an image area, a value of a parasitic capacitance is relatively increased. If a time margin is decreased according to pixel reading from the valid pixel region 821, a margin becomes inadequate for pixels in the OPB region 823 having a pixel reading speed that is lowered by a parasitic capacitance C₃_{_{—}}₂. It is therefore impossible to correctly and speedily read signal level from the pixels in the OPB region 823. As a result, only image in which black reference signals are out of alignment is generated.

In accordance with an aspect of the present invention for achieving the object, there is provided a solid-state imaging device in which a plurality of pixel cells are arrayed in a matrix in or on a semiconductor substrate, the pixel cells each including a photoelectric conversion element and a transistor connected to the photoelectric conversion element, the solid-state imaging device comprising: a valid pixel area including valid pixel cells from each of which an image signal corresponding to incident light is outputted, the valid pixel cells being included in the pixel cells; a light-blocking pixel area peripheral to the valid pixel area and including light-blocking pixel cells from each of which a black level signal independent of the incident light that is blocked is outputted, the light-blocking pixel cells being included in the pixel cells; and a peripheral circuit area peripheral to the valid pixel area and the light-blocking pixel area, the peripheral circuit area including a peripheral circuit that drives the pixel cells and performs signal processing, wherein, when (i) the valid pixel area has N line layers (where N is a natural number), (ii) the light-blocking pixel area has M line layers (where M is a natural number), (iii) the peripheral circuit area has L line layers (where L is a natural number), (iv) the valid pixel area, the light-blocking pixel area, and the peripheral circuit area share line layers up to an N-th line layer from a surface of the semiconductor substrate, and (v) N<M≦L, a light-blocking line layer among the line layers blocks light incident on photoelectric conversion elements in the light-blocking pixel area, and an interlayer insulating film is filled between the light-blocking line layer and the N-th line layer, the light-blocking line layer being one of an (N+2)th line layer and a line layer higher than the (N+2)th line layer.

With the above structure, a thickness of the interlayer insulating film between the light-blocking layer and the N-th line layer is greater than a gap between neighboring line layers. Therefore, a parasitic capacitance existing between the light-blocking layer and the N-th line layer is less than a parasitic capacitance between neighboring line layers. It is therefore possible to reduce a difference between a time required to read a black level signal from a light-blocking pixel and a time required to read a pixel signal from a valid pixel. The above structure enables high-speed reading of a black level signal having enough time margin from a light-blocking pixel. As a result, it is possible to obtain, at a high speed, image with correct black reference and with a small amount of noises even on the conditions where a light amount is small.

It is possible that N is 2, the peripheral circuit area has lines in all of a first line layer, a second line layer, a third line layer, and a fourth line layer from the surface of the semiconductor substrate, the valid pixel area has lines in the first line layer and the second line layer, and the light-blocking pixel area has lines in the first line layer, the second line layer, and the fourth line layer.

With the above structure, if an imaging area including the valid pixel area, the light-blocking pixel area, and the peripheral circuit area has four line layers, an interlayer insulating film fills the third line layer in the light-blocking pixel area and a light-blocking film is provided in the fourth line layer in the light-blocking pixel area. It is therefore possible to reduce a difference between a time required to read a black level signal from a light-blocking pixel and a time required to read a pixel signal from a valid pixel.

It is further possible that the light-blocking line layer includes a light-blocking film comprising aluminium.

In the conventional solid-state imaging device, the light-blocking film in the light-blocking pixel area is often provided in a plurality of line layers to ensure light-blocking performance. In contrast, in the above structure, the light-blocking film comprises aluminium so that the light-blocking performance is dramatically improved. As a result, even a small number of light-blocking layers one layer can block light.

It is still further possible that a light-blocking side wall is provided at least between the N-th line layer and the light-blocking line layer at a boundary between the valid pixel area and the light-blocking pixel area, the light-blocking side wall blocking light and comprising a heavy metal used in a via connecting the line layers.

The above structure can prevent deterioration of light-blocking performance on light incident from the valid pixel area oblique to the light-blocking pixel area, so that the light-blocking performance is dramatically improved. As a result, even if the number of line layers each including a light-blocking film is small, light can be blocked enough.

It is still further possible that the solid-state imaging further includes signal lines each provided at least for a corresponding one of columns of the pixels cells, the signal lines being used to read pixel signals generated in the valid pixel cells to outside of the valid pixel area, and used to read black level signals generated in the light-blocking pixel cells to outside of the light-blocking pixel area, wherein the light-blocking pixel area is provided along a direction of arranging rows of the valid pixel cells, and the signal lines are provided in the N-th line layer.

With the above structure, focusing attention to the signal line in the N-th line layer, the signal line in the light-blocking pixel has a parasitic capacitance which the signal line in the valid pixel does not have. In contrast, in the light-blocking pixel according to the present aspect, the region corresponding to the (N+1)th line layer that is located immediately above the N-th line layer in the valid pixel is not used as a line layer. However, the region is filled with the interlayer insulating film, and a light-blocking film is further provided in the (N+2)th line that is located immediately above the (N+1)th line layer. This structure can significantly reduce the parasitic capacitance of the signal line with respect to the light-blocking film.

It is still further possible that the solid-state imaging device further includes transfer control lines each provided at least for a corresponding one of rows of the pixel cells, the transfer control lines each being used to control transfer of charges generated in the photoelectric conversion element to a charge accumulation unit, wherein the light-blocking pixel area is provided along a direction of arranging columns of the valid pixel cells, and the transfer control lines are provided at least in the N-th line layer.

A light-blocking pixel and a valid pixel need to be controlled at the same regular timings over the whole pixel array. Therefore, (a) a time duration from rising of the transfer control signal to falling of the transfer control signal is preferably the same between a valid pixel and a light-blocking pixel. However, if influence of the light-blocking film on the parasitic capacitance is greater, a time required for the rising or a time required for the falling of the transfer control line in the light-blocking pixel is longer than that of the transfer control line in the valid pixel area. This means that a time period during which the transfer control signal is stable at HIGH or LOW level is shortened.

With the above structure, a parasitic capacitance of the transfer control line with respect to the light-blocking film can be reduced even in a light-blocking pixel. Therefore, it is possible to assure the time period during which the transfer control signal is stable at HIGH or LOW level is shortened. As a result, a horizontal scanning period can be shortened, and a frame rate can be increased for speeding up.

It is still further possible that the interlayer insulating film comprises a Low-k material.

This structure can reduce a value of the parasitic capacitance located between the light-blocking layer and the N-th line layer.

It is still further possible that the interlayer insulating film has a thickness that is at least twice as long as a distance between an (N−1)th line layer and the N-th line layer from the surface of the semiconductor substrate.

This structure can reduce a parasitic capacitance located between the light-blocking layer and the N-th line layer to roughly a half of the parasitic capacitance located between neighboring line layers. As a result, it is possible to approximate, at maximum, a time required to read a black level signal from a light-blocking pixel to a time required to read a pixel signal from a valid pixel.

The following describes embodiments of the present disclosure in detail with reference to the drawings.

### Embodiment 1

In a solid-state imaging device according to Embodiment 1, a plurality of pixel cells are arrayed in a matrix in or on a silicon substrate. Each of the pixels includes a photodiode and a transistor connected to the photodiode. The solid-state imaging device includes the following structural elements. A valid pixel area includes valid pixel cells from each of which an image signal corresponding to incident light is outputted. A horizontal OB area is provided peripheral to the valid pixel area and includes light-blocking pixel cells from each of which a black level signal independent of the incident light that is blocked is outputted. A peripheral circuit area is provided peripheral to the valid pixel area and the horizontal OB area. The peripheral circuit area includes a peripheral circuit that drives the pixel cells and performs signal processing. When (i) the valid pixel area has two line layers, (ii) the horizontal OB area has four line layers, and (iii) the valid pixel area, the horizontal OB area, and the peripheral circuit area share line layers up to the second line layer from a surface of the silicon substrate, the incident light on the horizontal OB area is blocked by the fourth line layer, and an interlayer insulating film is filled between the fourth line layer that blocks the incident light on the horizontal OB area and the second line layer.

The above structure enables high-speed reading of a black level signal having enough time margin from a light-blocking pixel. As a result, it is possible to obtain, at a high speed, image with correct black reference and with a small amount of noises even on the conditions where a light amount is small.

The following describes a solid-state imaging device according to Embodiment 1 in detail.

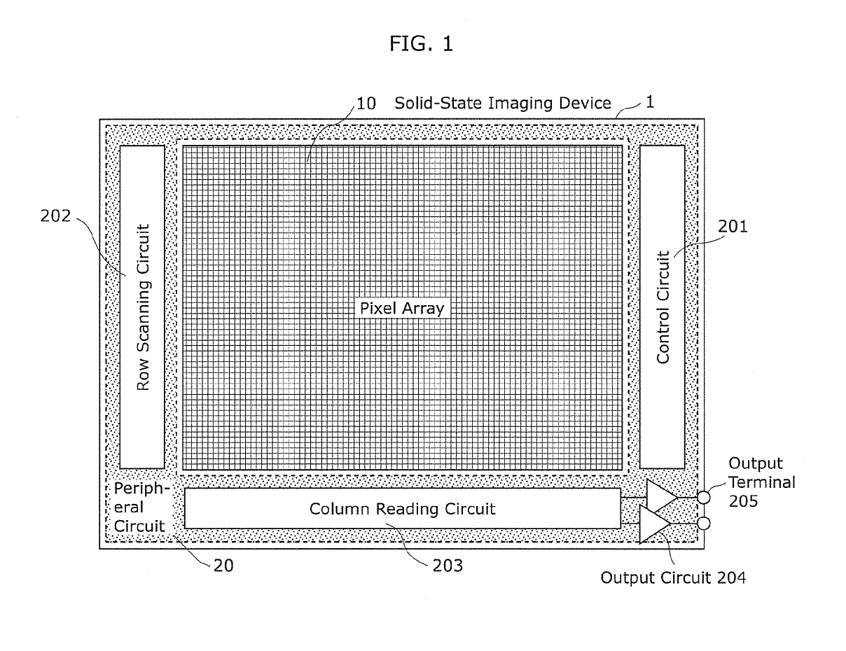

FIG. 1 is a schematic diagram showing a structure of the solid-state imaging device according to Embodiment 1. In the solid-state imaging device 1 shown in FIG. 1, a pixel array 10 is arranged roughly at the center of the solid-state imaging device 1, and a peripheral circuit 20 is provided at periphery of the pixel array 10. The peripheral circuit 20 includes a row scanning circuit 202, a column reading circuit 203, and a control circuit 201. For the sake of convenience, FIG. 1 shows these circuits to the left side, to the right side, and under the pixel array 10. However, the positional relationship among the circuits and the pixel array 10 is not limited to the above.

In the pixel array 10, pixels each including a photoelectric conversion element are arrayed two-dimensionally. Light incident on the pixel array 10 is converted into electrical charges and accumulated in these pixels.

The row scanning circuit 202 sequentially selects rows of pixels in the pixel array 10 one by one to perform pixel control. More specifically, the row scanning circuit 202 resets the selected pixels or read signals from the pixels.

The column reading circuit 203 receives electrical signals read from pixel to perform necessary processing on them. The electrical signals generally indicate voltage changes. If the column reading circuit 203 serves to output analog signals, such column reading circuit 203 often performs so-called Correlated Double Sampling (CDS) processing, signal amplification, and the like. In contrast, if the column reading circuit 203 serves to output digital signals, such column reading circuit 203 performs A/D conversion or other digital signal processing in addition to the above processing. The output signals of the column reading circuit 203 are provided to an output circuit 204, and then outputted from an output terminal 205.

For analog output, an analog amplifier is used as the output circuit 204. For digital output, when a high speed is particularly required, a high-speed differential signal output I/F circuit is used as the output circuit 204. The structure of the output circuit 204 and the number of terminals included in the output circuit 204 are various depending on uses of the solid-state imaging device. However, the advantageous effects of the present invention are not influenced by the structure of the output circuit 204. Therefore, the structure is not described in this disclosure.

The peripheral circuit 20 drives pixels and performs pixel processing. The peripheral circuit 20 is provided in a peripheral circuit area. If the number of metal line layers is small, a layout effectiveness is significantly deteriorated, and it becomes difficult to perform processing at a high speed. Therefore, for example, at least four metal line layers are necessary.

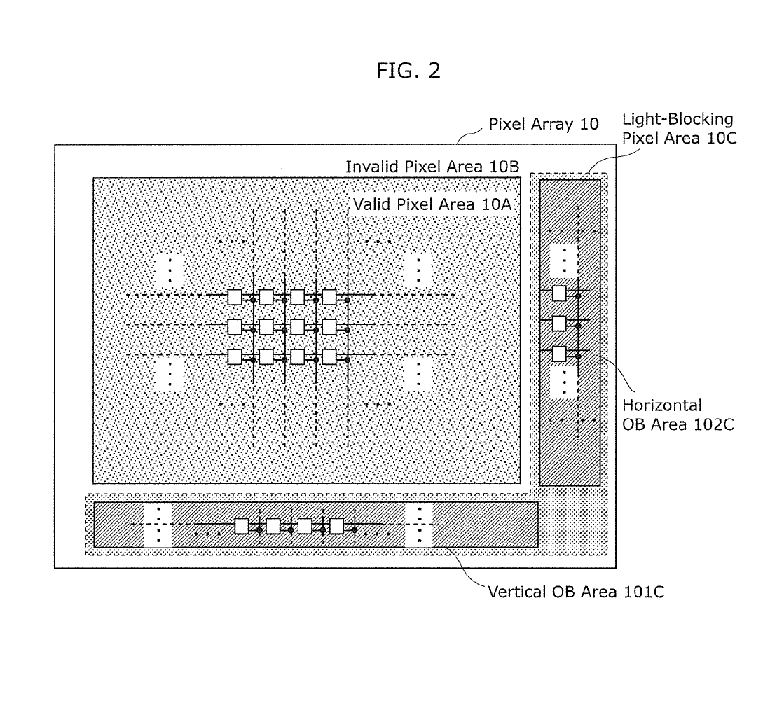

FIG. 2 is a schematic diagram showing the structure of the pixel array according to Embodiment 1. The pixel array 10 shown in FIG. 2 includes a valid pixel area 10A, a light-blocking pixel area 10C, and an invalid pixel area 10B.

The valid pixel area 10A includes a plurality of valid pixels. In the valid pixels, incident light propagated through an optical lens from an object is formed as a two-dimensional image. Image signals corresponding to respective points on the image are outputted from the valid pixels.

In the light-blocking pixel area 10C, a plurality of light-blocking pixels are arranged on the same plane where the valid pixels are provided. Each of the light-blocking pixels basically has the same structure as that of the valid pixel, although the light-blocking pixels block light. For the light-blocking pixels, the same control and the same signal reading as described for the valid pixels are performed. As a result, each light-blocking pixel outputs black level signal indicating a brightness level of a pixel signal.

The invalid pixel area 10B includes invalid pixels. Each of the invalid pixels has the same, or almost the same structure as that of the valid pixel or the light-blocking pixel. Output signals of the invalid pixels are not used.

The light-blocking pixel area 10C includes a vertical OB area 101C and a horizontal OB area 102C. The horizontal OB area 102C is located on the left or right side (or on left and right sides) of the valid pixel area 10A along a direction of arranging rows. When signals are read from valid pixels by scanning a pixel row, a black level signal is outputted from a row in the horizontal OB area 102C at the same time. The vertical OB area 101C is located above or under (or above and under) of the valid pixel area 10A along a direction of arranging columns. In the vertical OB area 101C, black level signals are outputted during a period from an end of reading signals from valid pixels in a current frame to a start of reading signals from valid pixels in a next frame.

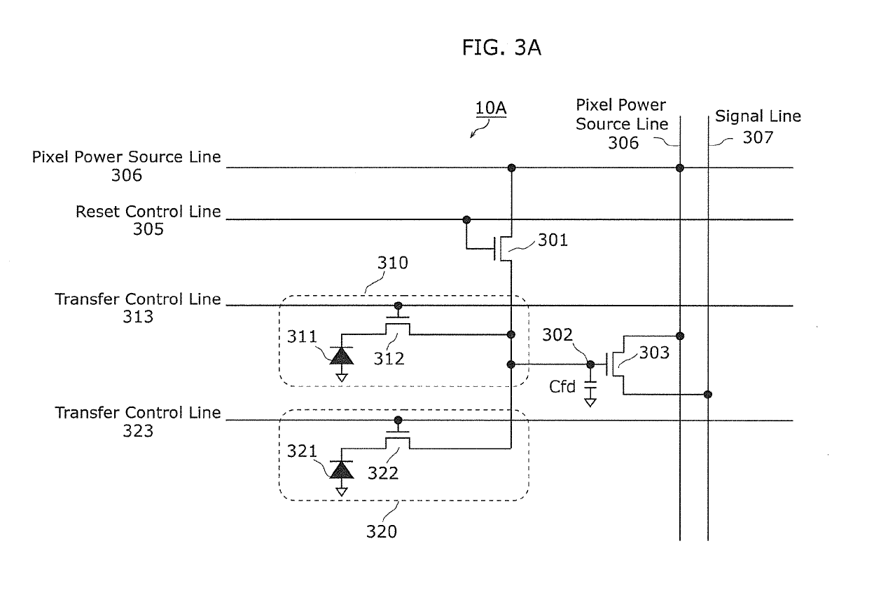

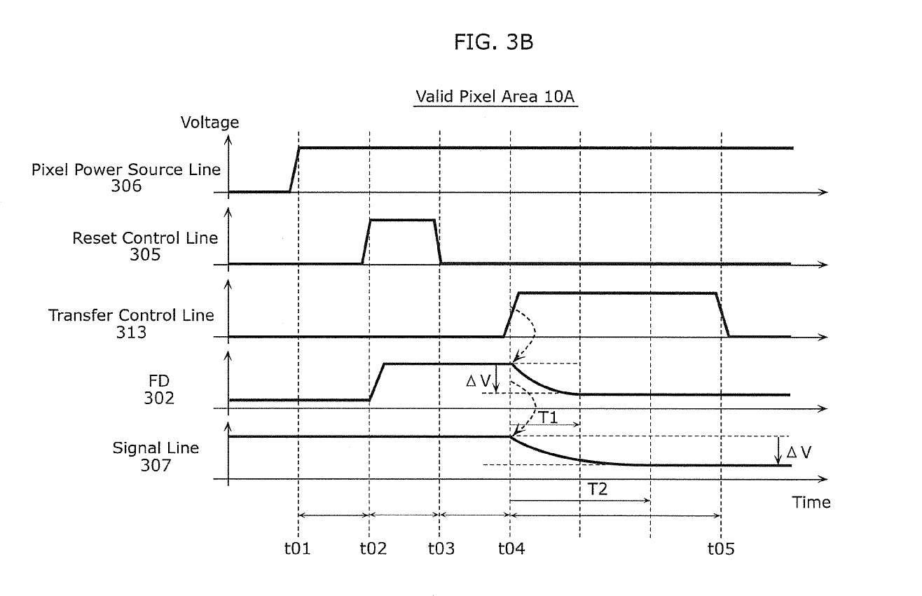

FIG. 3A is a schematic diagram showing a detailed structure of a pixel circuit in the valid pixel area according to Embodiment 1. The valid pixel area 10A has valid pixels that include two valid pixels 310 and 320 as shown in the figure. The valid pixels 310 and 320 share a reset transistor (RS) 301, a charge accumulation unit (FD) 302, and a source follower transistor (SF) 303. In other words, the valid pixel 310, the valid pixel 320, the RS 301, the FD 302, and the SF 303 form a unit cell (hereinafter, referred to as a “single pixel cell” or a “pixel cell”) that is a unit in a periodic structure of the pixel array. In the valid pixel area 10A, a plurality of pixel cells are arrayed in a matrix. Each of pixel circuits in the valid pixel area 10A according to the present embodiment does not include a selection transistor. It should be noted that the structure of the valid pixel according to the present disclosure is not limited to the above.

The valid pixel 310 includes a photodiode (PD) 311 and a transfer transistor (TG) 312. The PD 311 converts incident light to electrical charges and accumulates them. The TG 312 transfers the charges accumulated in the PD 311 to the FD 302 according to transfer control signal provided from a transfer control line 313.

The valid pixel 320 includes a PD 321 and a TG 322. The PD 321 converts incident light to electrical charges and accumulates them. The TG 322 transfers the charges accumulated in the PD 321 to the FD 302 according to transfer control signal provided from a transfer control line 323.

The SF 303 outputs a signal to a signal line 307 according to a level of the FD 302.

The RS 301 initializes the FD 302 according to a reset signal provided from a reset control line 305. A drain of the RS 301 and a drain of the SF 303 are connected to a pixel power source line 306.

A signal line 307 is provided to at least each of rows of pixel cells. Through the signal line 307, a pixel signal generated in a pixel cell in the valid pixel area 10A is read to the outside of the valid pixel area 10A.

It should be noted that the light-blocking pixel described below has almost the same circuit structure as that of the valid pixel, except that the light-blocking pixel has a light-blocking film to block incident light.

The brief description is given for reading form a pixel circuit in the valid pixel area 10A having the above-described structure with reference to a time chart of FIG. 3B.

FIG. 3B is a time chart for explaining reading performed in a pixel circuit in the valid pixel area according to Embodiment 1.

First, in an initial state, the pixel power source line 306 and the reset control line 305 are at LOW potential. Here, the FD 302 is at LOW level, and the SF 303 is OFF.

At time t01, the pixel power source line 306 is set to HIGH potential.

At time t02, the reset control line 305 corresponding to a target row is set to HIGH potential, and the RS 301 is turned ON. Here, the FD 302 is reset to HIGH.

At time t03, the reset control line 305 is set to LOW potential, and the RS 301 is turned OFF.

At time t04, the transfer control line 313 is set to HIGH potential and the TG 312 is turned ON, so that charges Q accumulated in the PD 311 by photoelectric conversion are transferred to the FD 302. As a result, after time t04, the potential level of the FD 302 is changed, and the change is outputted to the signal line 307 via the SF 303. Here, the change of the potential level in the FD 302 is expressed by following Mathematical Formula 3.

ΔV=Q/Cfd (Mathematical Formula 3)

where Cfd represents a parasitic capacitance of the FD 302.

The operations of a load circuit and the SF 303 connected to the signal line 307 cause the potential level change ΔV of the FD 302 to be propagated as gain of roughly 1 and then outputted from the pixel array 10. Here, when T1 represents a time duration required for completion of transfer from the PD 311 to the FD 302 and T2 represents a time duration required for signal propagation via the signal line 307 to the outside of the pixel array 10, T2 is longer than T1 due to influence of a Resistance Capacitance (RC) time constant of the signal line 307. Furthermore, T2 is longer as the number of pixels is increased.

The above-described processing completes the reading from the PD 311. When charges accumulated in the PD 321 are to read out, basically the same control can be used, although the transfer control line 323 not the transfer control line 313 is controlled.

It should be noted in the present embodiment that, for example, the two PDs 311 and 321 share a single SF 303 in a pixel cell structure. However, when more photodiodes share the single SF 303, a plurality of sets each including a photodiode, a transfer transistor, and a transfer control line are connected in parallel, in the same manner as the valid pixels 310 and 320.

Next, in order to explain a difference of characteristics between a valid pixel and a light-blocking pixel, a planar layout of the pixel array 10 is described.

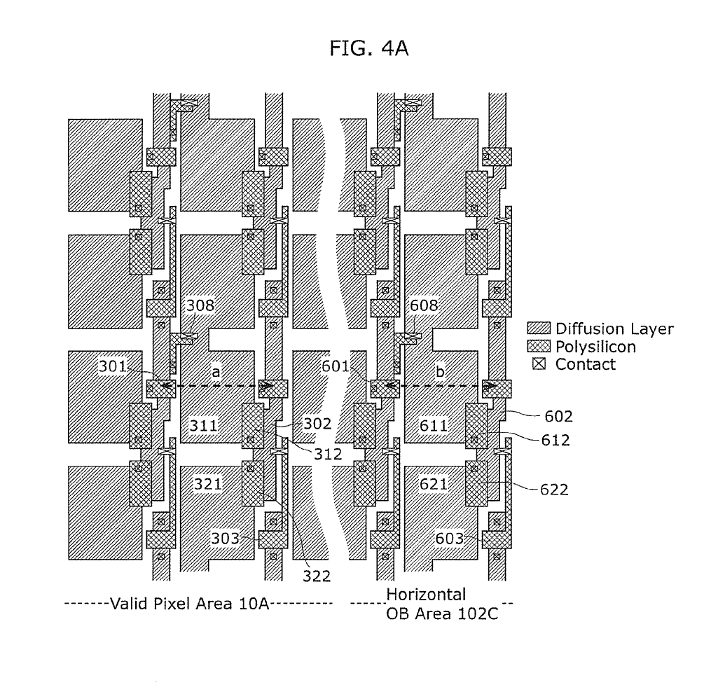

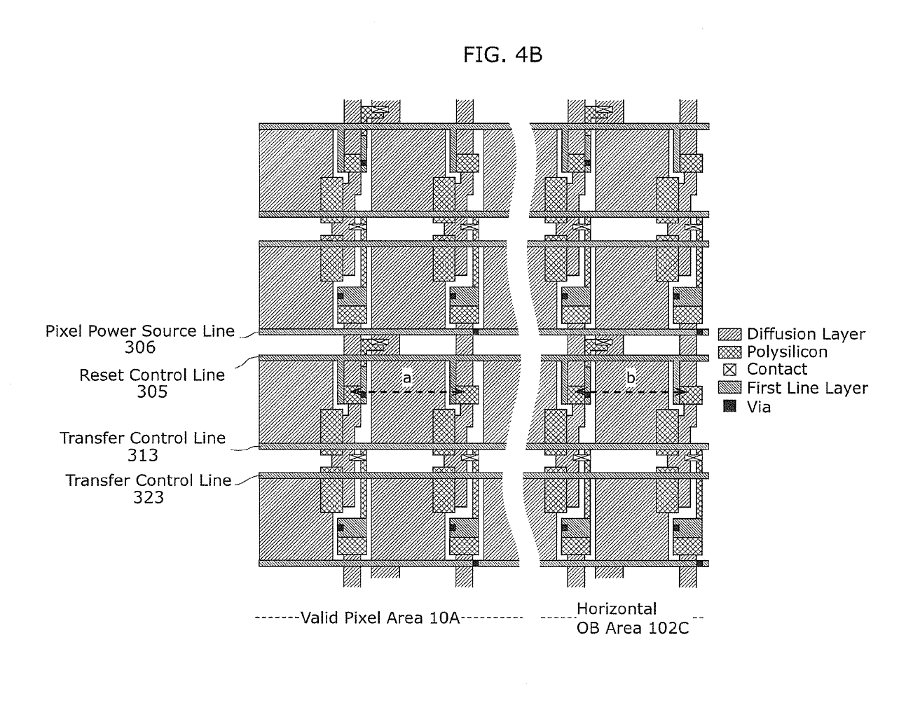

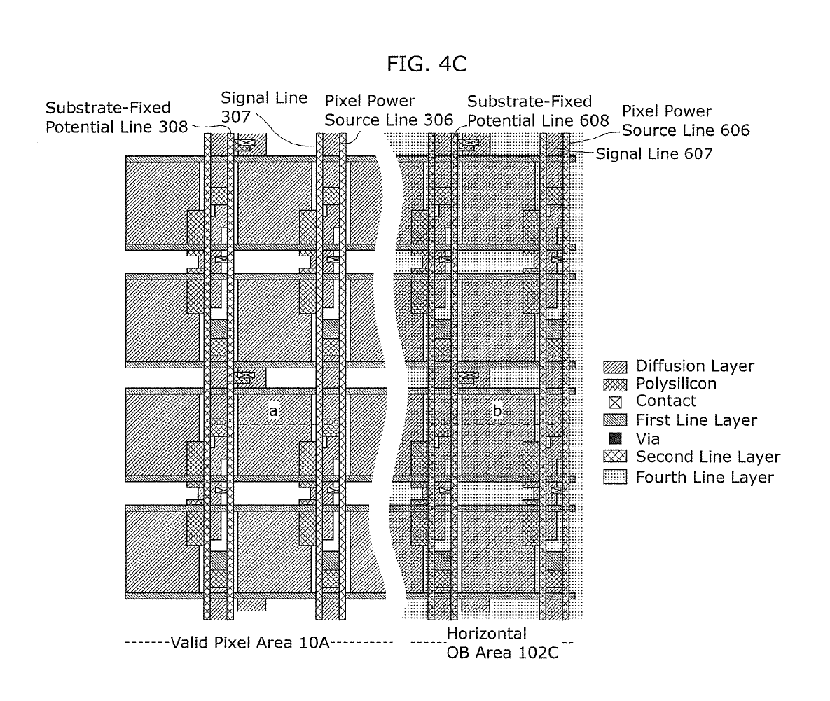

FIG. 4A is a planar layout diagram showing a silicon substrate that includes a diffusion layer, polysilicon, and contacts, according to Embodiment 1. FIG. 4B is a planar layout diagram showing the silicon substrate and a first line layer formed above the silicon substrate, according to Embodiment 1. FIG. 4C is a planar layout diagram showing: the silicon substrate; the first line layer formed above the silicon substrate; a second line layer; and a fourth line layer, according to Embodiment 1.

Each of FIGS. 4A to 4C is a diagram showing a part of the pixel array 10. Each diagram shows the valid pixel area 10A on the left side, and the horizontal OB area 102C on the right side.

FIG. 4A shows a diffusion layer, polysilicon, and contacts, all of which are included in the silicon substrate. In each of the valid pixel area 10A and the horizontal OB area 102C, photodiodes and transfer transistors are arranged. The photodiodes (PDs 311, 321, 611, 621, and the like in FIG. 4A) are provided at equal distances along a column direction. The transfer transistors (TGs 312, 322, 612, 622, and the like in FIG. 4A) are provided to correspond to the respective photodiodes. More specifically, each of the transfer transistors is provided to the upper right or the lower right of a corresponding photodiode. In the figure, among four photodiodes and four transfer transistors provided along each column, the lower two photodiodes and the lower two transfer transistors are assigned with the reference numerals used in the circuit diagram of FIG. 3A. In short, they are the PD 311, the PD 321, the PD 611, the PD 621, the TG 312, the TG 322, the TG 612, and the TG 622.

FIG. 4A also shows the SF 303 and the RS 301. The SF 303 has a gate connected to drains of these two transfer transistors. The RS 301 has a source that is also connected to the drains of the two transfer transistors.

FIG. 4B shows: the silicon substrate shown in FIG. 4A; the first line layer located above the silicon substrate; and vias connecting the first line layer to the second line layer. In the valid pixel area 10A and the horizontal OB area 102C shown in FIG. 4B, the first line layer is located above the silicon substrate. The first line layer includes: transfer control lines (transfer control lines 313, 323, and the like in FIG. 4B) each connected to a gate of a corresponding transfer transistor; a pixel power source line 306 connected to the drain of the SF 303 and the drain of the RS 301; and reset control lines (reset control lines 305 and the like in FIG. 4B) connected to the gate of the RS 301.

FIG. 4C shows: the silicon substrate shown in FIG. 4B; the first line layer and the vias; the second line layer located above the first line layer and the vias; and a fourth line layer located above the second line layer. In the valid pixel area 10A and the horizontal OB area 102C shown in FIG. 4C, the second line layer is provided above the first line layer. The second line layer includes: signal lines (signal lines 307, 607, and the like in FIG. 4C); a pixel power source line 306 connected to the drain of the SF 303 and the drain of the RS 301; and substrate-fixed potential lines (substrate-fixed potential lines 308, 608, and the like in FIG. 4C). In addition, in the horizontal OB area 102C shown in FIG. 4C, the fourth line layer is provided above a third line layer. The fourth line layer covers the horizontal OB area 102C to serve as a light-blocking film that blocks light incident on the photodiodes.

Here, in the peripheral circuit 20, the third line layer is provided between the second line layer and the fourth line layer. On the other hand, in the horizontal OB area 102C, an interlayer insulating film is provided to a position corresponding to the third line layer. Moreover, the first to fourth line layers are arranged roughly at equal distances in a direction of stacking the layers.

In other words, a thickness of the interlayer insulating film between the second line layer and the fourth line layer in the horizontal OB area 102C is equal to or more than twice as long as a distance between the first line layer and the second line layer.

The horizontal OB area 102C further differs from the valid pixel area 10A in that the fourth line layer covers the entire horizontal OB area 102C.

The above-described layout is characterized in that the transfer control lines and the reset control lines are provided in the first line layer, the signal lines and the substrate-fixed potential lines are provided in the second line layer, the pixel power source lines are provided in both the first and second line layers, and the light-blocking film is provided in the fourth line layer.

Next, a cross-sectional surface structure is compared between the above-described pixel array 10 according to the present embodiment and a conventional pixel array.

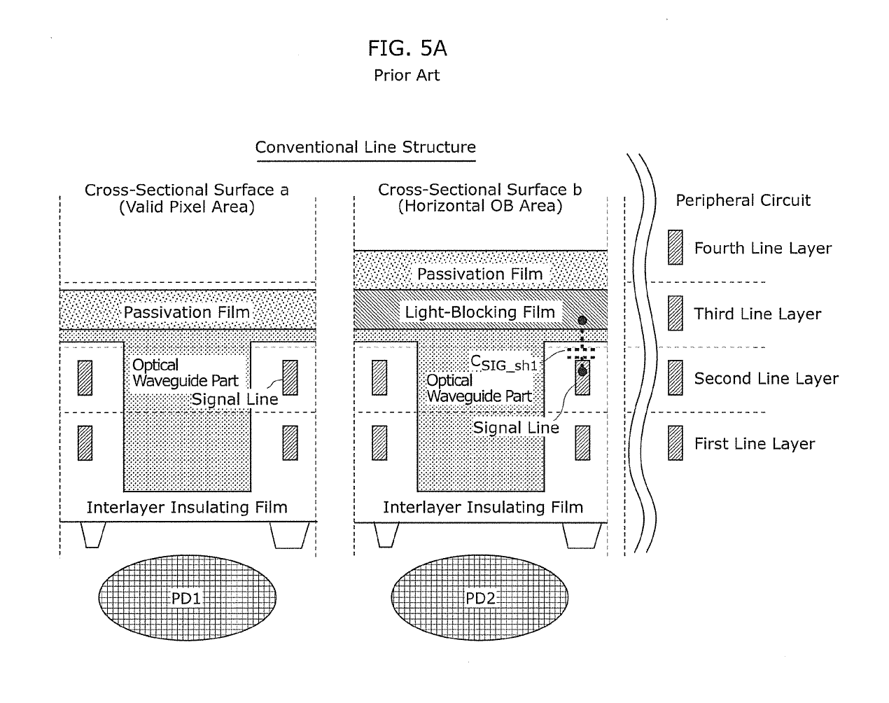

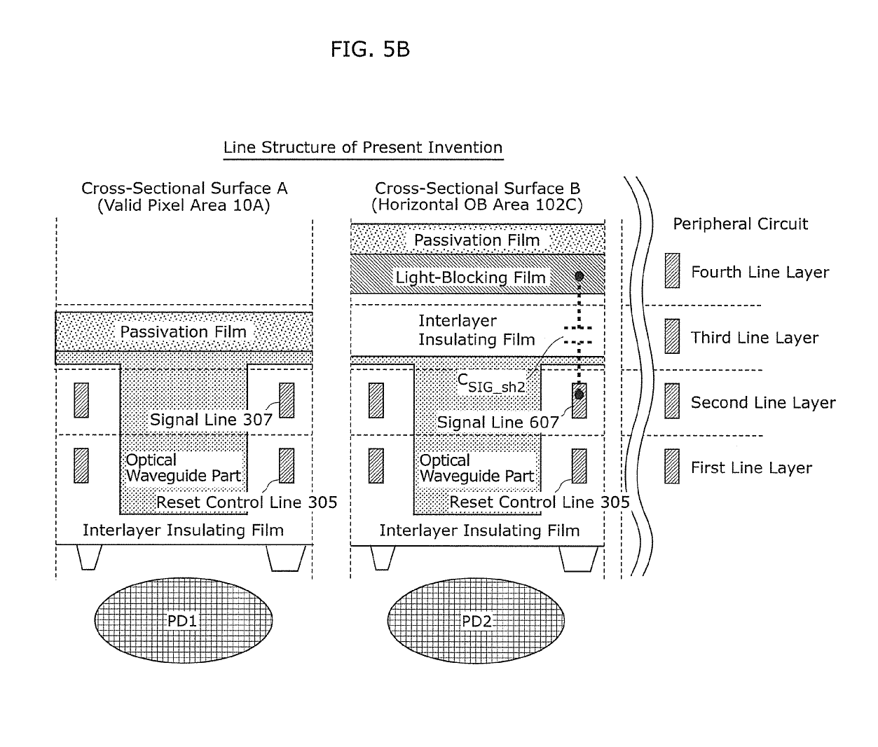

FIG. 5A is a cross-sectional view of pixels in a conventional solid-state imaging device. FIG. 5B is a cross-sectional view of pixels in the solid-state imaging device according to Embodiment 1. In both figures, a cross-sectional view on the left side shows a part taken along a broken line “a” in the valid pixel in the planar layout shown in FIGS. 4A to 4C. On the other hand, in both figures, a cross-sectional view on the right side shows a part taken along a broken line “b” in the light-blocking pixel in the planar layout shown in FIGS. 4A to 4C. In each of the valid pixel and the light-blocking pixel, a photodiode is provided in the silicon substrate. Above the photodiode, an optical waveguide part is provided. The optical waveguide part is made of a material having a high refractive index, such as SiN, to increase light-collection efficiency of the photodiode. In the first line layer and the second line layer, various lines are arranged at both sides of the optical waveguide part. The space between the various lines and the optical waveguide part is filled with an interlayer insulating film. Regarding the peripheral circuit, the first to fourth line layers are arranged roughly at equal distances in a direction of stacking the layers.

Regarding the valid pixel area, both in FIGS. 5A and 5B, the respective valid pixels have the same line layout. On the other hand, regarding the horizontal OB area, the respective light-blocking pixels have different structures in FIGS. 5A and 5B. More specifically, in FIG. 5A showing the light-blocking pixel in the conventional solid-state imaging device, the light-blocking film is provided in the third line layer, while in FIG. 5B showing the light-blocking pixel in the solid-state imaging device of the present disclosure, the light-blocking film is provided in the fourth line layer.

In each of the structures, focusing attention to the signal line in the second line layer, the signal line in the light-blocking pixel has a parasitic capacitance C_{SIG}_{_{—}}ₛₕ₁ or C_{SIG}_{_{—}}ₛₕ₂, which the signal line in the valid pixel does not have. In order to reduce such a parasitic capacitance, in the light-blocking pixel according to the present disclosure in FIG. 5B, the region corresponding to the third line layer that is located above the second line layer as the top line layer in the valid pixel is not used as a line layer. However, in the light-blocking pixel according to the present disclosure in FIG. 5B, the region is filled with an interlayer insulating film, and a light-blocking film is further provided above the interlayer insulating film as the fourth line layer. This structure can significantly reduce the parasitic capacitance of the signal line with respect to the light-blocking film from C_{SIG}_{_{—}}ₛₕ₁ to C_{SIG}_{_{—}}ₛₕ₂.

In the line layout according to the present embodiment, in the first line layer, a transfer control line and a reset control line are shared both in the valid pixel area 10A and in the horizontal OB area 102C, while in the second layer, different signal lines are provided independently in the valid pixel area 10A and in the horizontal OB area 102C. In other words, parasitic capacitances of the signal line 607 with respect to the light-blocking film in the horizontal OB area 102C directly influence a difference of reading characteristics between the light-blocking pixels and the valid pixels. The difference is greater as the number of pixel rows is increased. Therefore, in the pixel array having the horizontal OB area 102C, it is greatly advantageous to increase a distance between the signal line and the light-blocking film to reduce the parasitic capacitance C_{SIG}_{_{—}}ₛₕ₂.

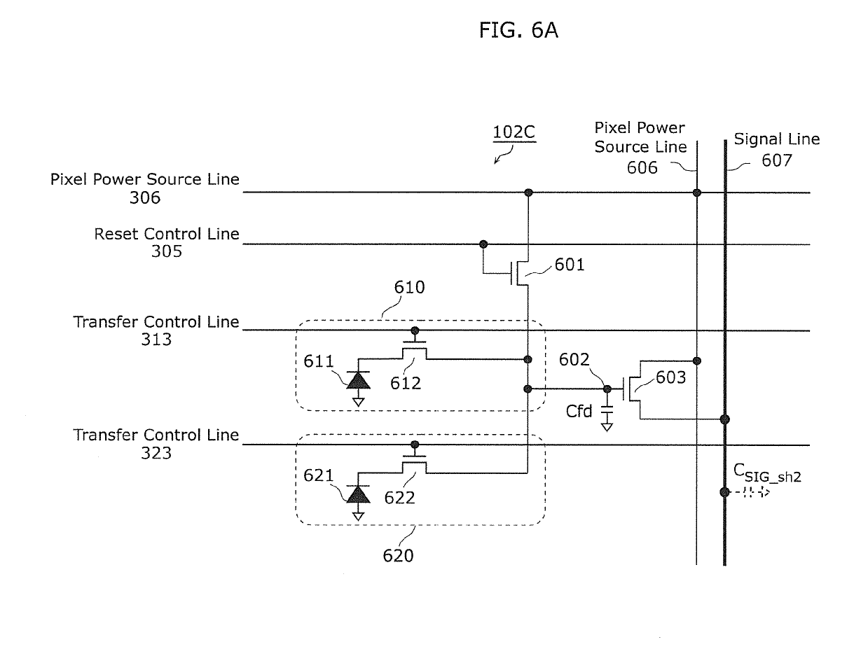

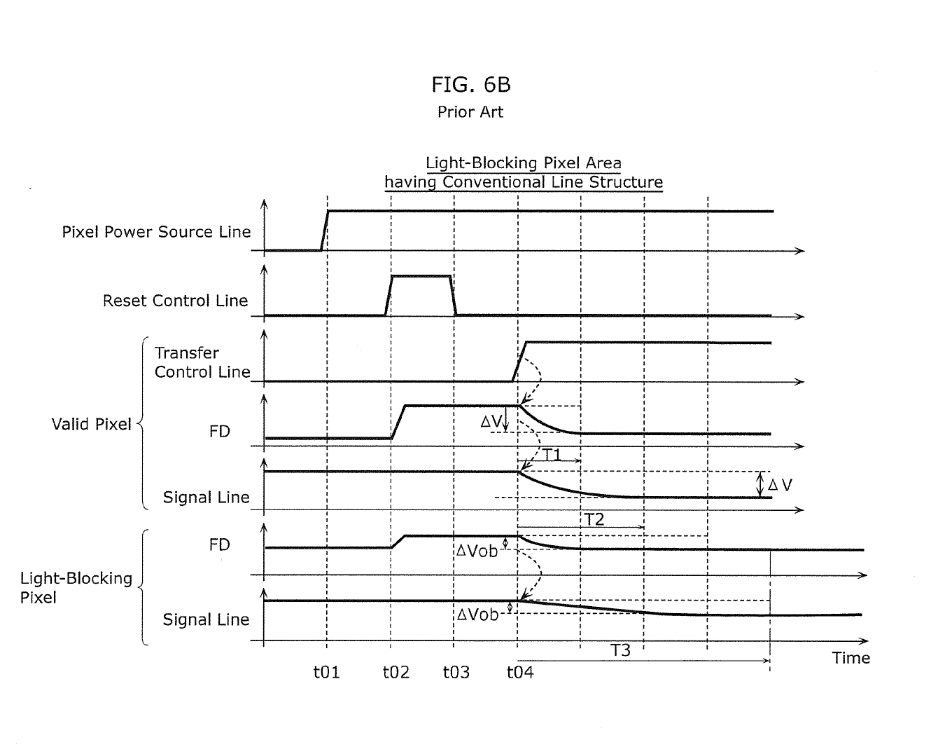

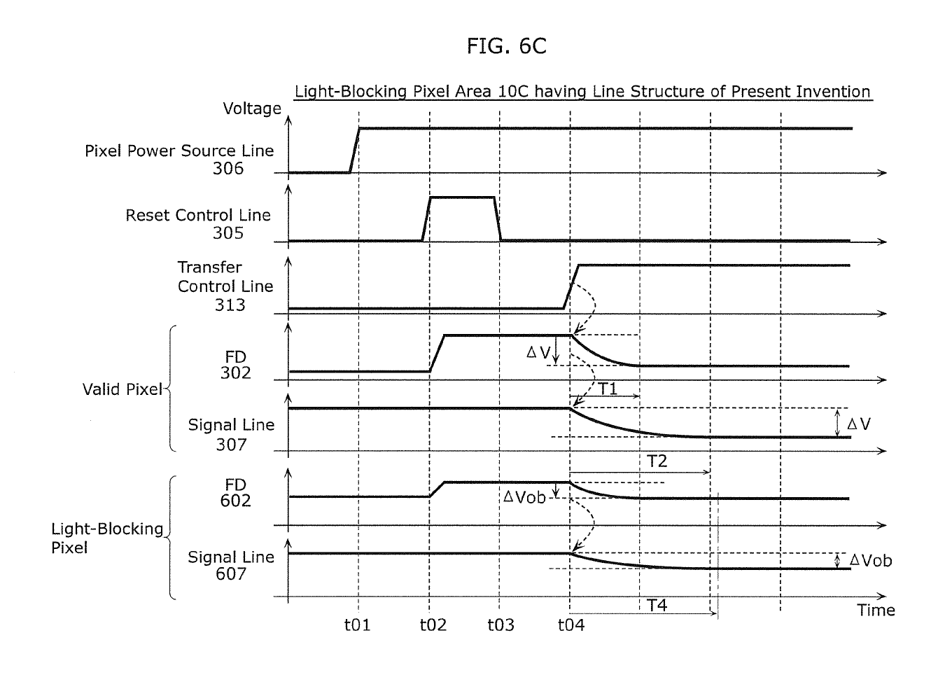

FIG. 6A is a circuit diagram showing a parasitic capacitance in a light-blocking pixel according to Embodiment 1. The parasitic capacitance is a difference between a layout of a light-blocking pixel and a layout of a valid pixel. The horizontal OB area 102C has light-blocking pixels that include light-blocking pixels 610 and 620 shown in FIG. 6A. The light-blocking pixels 610 and 620 share an RS 601, an FD 602, and an SF 603. In other words, the light-blocking pixel 610, the light-blocking pixel 620, the RS 601, the FD 602, and the SF 603 form a single pixel cell. In the horizontal OB area 102C, a plurality of such pixel cells are arranged in a matrix. The light-blocking pixel 610 includes a PD 611 and a TG 612. The light-blocking pixel 620 includes a PD 621 and a TG 622. The SF 603 outputs signals to the signal line 607 according to a level of the FD 602. As described above, although the reference numerals assigned to the structural elements are different, the circuit structure is the same as that of the valid pixel shown in FIG. 3A. FIG. 6A differs from FIG. 3A in that a parasitic capacitance C_{SIG-sh2} occurs between the signal line 607 in the second line layer and a light-blocking film in the fourth line layer.

FIG. 6B is a time chart in which a reading waveform of a valid pixel is compared to a reading waveform of a light-blocking pixel in the conventional solid-state imaging device. FIG. 6C is a time chart in which a reading waveform of a valid pixel is compared to a reading waveform of a light-blocking pixel in the solid-state imaging device according to Embodiment 1.

In both FIGS. 6B and 6C, the operations of the valid pixel are the same as described with reference to FIG. 3B. A potential level change ΔV of a FD is propagated as gain of roughly 1, and outputted from the pixel array. Here, when T2 represents a time duration required for the signal propagation via the signal line to the outside of the pixel array, T2 is longer than T1 due to influence of an RC time constant of the signal line.

In contrast, in the conventional light-blocking pixel shown in FIG. 6B, due to influence of the parasitic capacitance C_{SIG}_{_{—}}ₛₕ₁ of the signal line with respect to the light-blocking film, a time duration T3 required for reading from the light-blocking pixel is roughly twice as long as the time duration T2 for reading from a valid pixel.

On the other hand, in the light-blocking pixel according to the present disclosure shown in FIG. 6C, a thickness of the interlayer insulating film between the second line layer and the fourth line layer in the horizontal OB area 102C is roughly twice as long as a distance between the first line layer and the second line layer. Therefore, the parasitic capacitance C_{SIG}_{_{—}}ₛₕ₂ of the signal line with respect to the light-blocking film is reduced to a half of the parasitic capacitance C_{SIG}_{_{—}}ₛₕ₁, so that a time duration T4 required for reading from the light-blocking pixel having the above structure is roughly equal to the time duration T2 required for reading from the valid pixel.

The above structure enables high-speed reading of a black level signal having an enough time margin from a light-blocking pixel in the horizontal OB area 102C. As a result, it is possible to provide a solid-state imaging device capable of obtaining, at a high speed, image with correct black reference and with a small amount of noises even on the conditions where a light amount is small.

It is preferable that the light-blocking film provided in the fourth line layer in the horizontal OB area 102C is made of aluminium. In the conventional solid-state imaging device 800, the light-blocking film is located in two layers which are the line layers 3MT and 4MT. However, in the solid-state imaging device according to the present embodiment, the light-blocking film is located only in one layer that is the fourth line layer. Since the light-blocking film comprises aluminium, the light-blocking performance is dramatically improved. As a result, one layer is enough to block light. It is also possible that the light-blocking film is made of copper. In this case, the light-blocking performance can be kept, if a color filter provided above the valid pixels is a black filter having high light-blocking performance.

It is further possible that, in order to decrease a difference of a line load between a valid pixel and a light-blocking pixel, the interlayer insulating film between the fourth line layer and the second line layer in the horizontal OB area 102C may comprise a so-called Low-k material having a low permittivity. Thereby, it is possible to decrease the value of the parasitic capacitance between the light-blocking film in the fourth line layer and the line in the second line layer.

It should be noted that it has been described in the present embodiment that each of the horizontal OB area and the peripheral circuit area has four line layers, but the present invention is not limited to the structure. More specifically, the present invention may be any solid-state imaging device that, when (i) the valid pixel area has N line layers (where N is a natural number), (ii) the horizontal OB area has M line layers (where M is a natural number), (iii) the peripheral circuit area has L line layers (where L is a natural number), (iv) the valid pixel area, the horizontal OB area, and the peripheral circuit area share line layers up to an N-th line layer from a surface of the semiconductor substrate, and (v) N<M L, a light-blocking line layer among the line layers blocks light incident on photoelectric conversion elements in the horizontal OB area, and an interlayer insulating film is filled between the light-blocking line layer and the N-th line layer, the light-blocking line layer being one of an (N+2)th line layer and a line layer higher than the (N+2)th line layer. Such a solid-state imaging device can offer the same effects.

### Embodiment 2

A pixel array in a solid-state imaging device according to Embodiment 2 differs from the pixel array 10 according to Embodiment 1 in that four pixels each having a photodiode and a transfer transistor share the same FD, the same reset transistor, and the same source follower transistor, that a reset potential of the FD is supplied form a reset power source line, and that the pixel array includes the valid pixel area and a vertical OB area. The following describes only differences from the solid-state imaging device according to Embodiment 1, not explaining again the same structures as described previously.

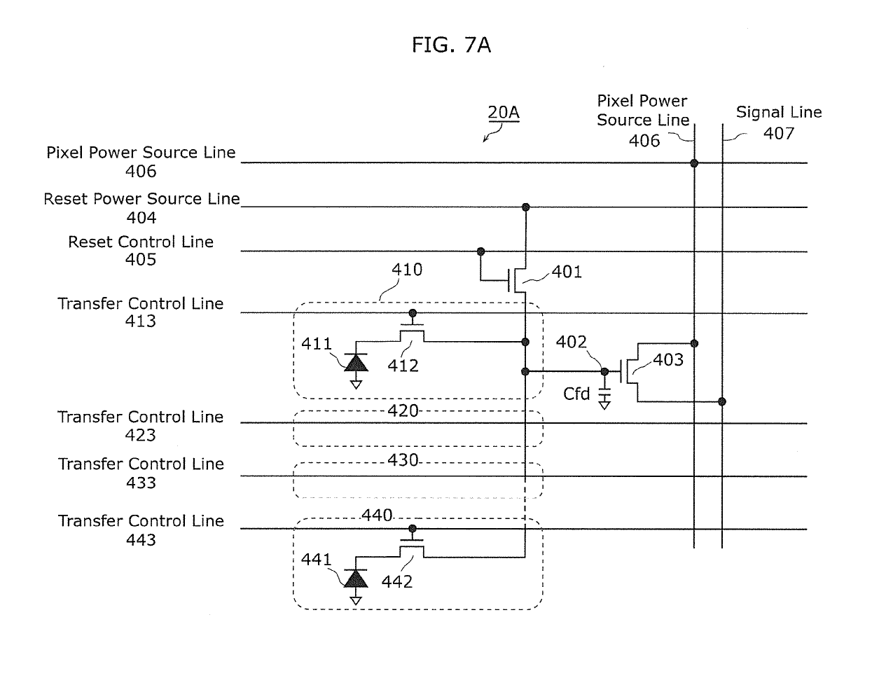

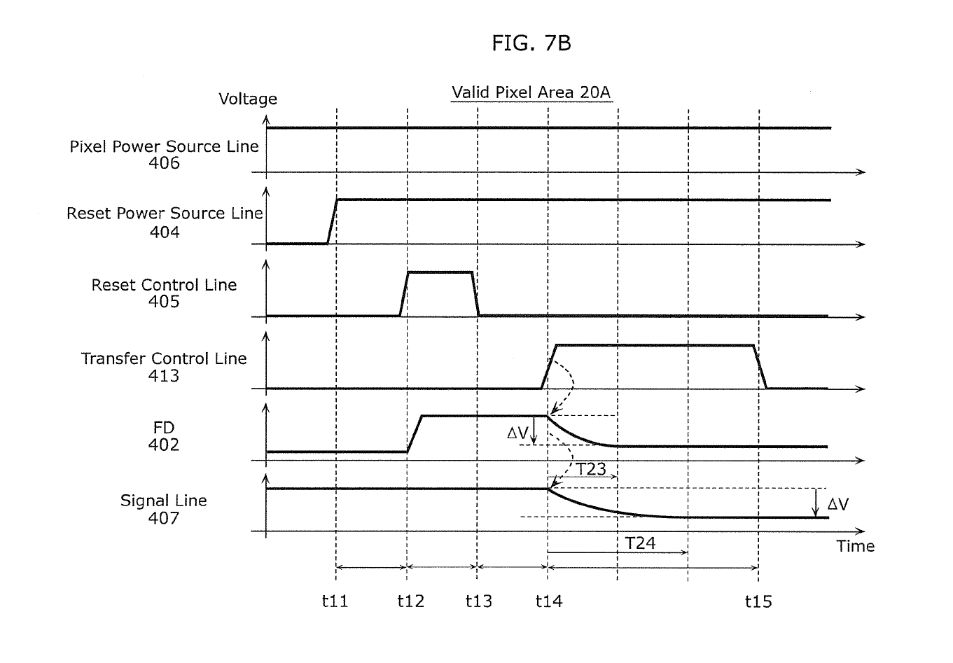

FIG. 7A shows a detailed structure of a pixel circuit in the valid pixel area according to Embodiment 2. A valid pixel area 20A has valid pixels that include four valid pixels 410, 420, 430, and 440 shown in FIG. 7A. The four valid pixels share an RS 401, an FD 402, and an SF 403. In other words, all of the valid pixels 410, 420, 430, and 440, the RS 401, the FD 402, and the SF 403 form a single pixel cell. In the valid pixel area 20A, a plurality of such pixel cells are arranged in a matrix. Each of the pixel circuits in the valid pixel area 20A does not include a selection transistor. It should be noted that the structure of the valid pixel according to the present disclosure is not limited to the above.

The valid pixel 410 includes a PD 411 and a TG 412. The PD 411 converts incident light to electrical charges and accumulates them. The TG 412 transfers the charges accumulated in the PD 411 to the FD 402 according to transfer control signal provided from a transfer control line 413. The valid pixels 420, 430, and 440 also have the same structure as that of the valid pixel 410.

The SF 403 outputs a signal to the signal line 407 according to a level of the FD 402.

The RS 401 initializes the FD 402 according to a reset signal provided from a reset control line 405.

Here, unlike Embodiment 1, a drain of the RS 401 is connected to a reset power source line 404, and a drain of the SF 403 is connected to a pixel power source line 406.

Here, the light-blocking pixel described later has basically the same pixel circuit as that of the valid pixel, except that the light-blocking pixel has a light-blocking film to block incident light.

The brief description is given for reading from the pixel circuit having the above-described structure in the valid pixel area 20A with reference to a time chart of FIG. 7B.

FIG. 7B is a time chart for explaining reading from a pixel circuit in the valid pixel area according to Embodiment 2.

First, in an initial state, the reset power source line 404 and the reset control line 405 are at LOW potential. Here, the FD 402 is at LOW level, and the SF 403 is OFF.

At time t11, the reset power source line 404 is set to HIGH potential.

At time t12, the reset control line 405 corresponding to a target row is set to HIGH potential, and the RS 401 is turned ON. Here, the FD 402 is reset to HIGH.

At time t13, the reset control line 405 is set to LOW potential, and the RS 401 is turned OFF.

At time t14, the transfer control line 413 is set to HIGH potential and the TG 412 is turned ON, so that charges Q accumulated in the PD 411 by photoelectric conversion are transferred to the FD 402. As a result, after time t14, the potential level of the FD 402 is changed, and the change is outputted to the signal line 407 via the SF 403. Here, the change of the potential level in the FD 402 is expressed by following Mathematical Formula 4.

ΔV=Q/Cfd (Mathematical Formula 4)

where Cfd represents a parasitic capacitance of the FD 402.

The operations of a load circuit and the SF 403 connected to the signal line 407 cause the potential level change ΔV of the FD 402 to be propagated as gain of roughly 1 and then outputted from the pixel array. Here, when T23 represents a time duration required for completion of transfer from the PD 411 to the FD 402 and T24 represents a time duration required for the signal propagation via the signal line 407 to the outside of the pixel array, T24 is longer than T23 due to influence of a RC time constant of the signal line 407. Furthermore, T24 is longer as the number of pixels is increased.

The above-described processing completes the reading from the PD 411. When charges accumulated in the PDs 421, 431, and 441 are to read out, basically the same control can be used, although the transfer control lines 423, 433, and 443 are controlled instead of the transfer control line 413.

It should be noted in the present embodiment that, for example, the four PDs 411, 421, 431, and 441 share the single SF 403 and the like in the pixel cell structure. However, when more photodiodes share the single SF 403, a plurality of sets each including a photodiode, a transfer transistor, and a transfer control line are connected in parallel, in the same manner as the four valid pixels.

Next, in order to explain a difference of characteristics between a valid pixel and a light-blocking pixel, a planar layout of the pixel array is described.

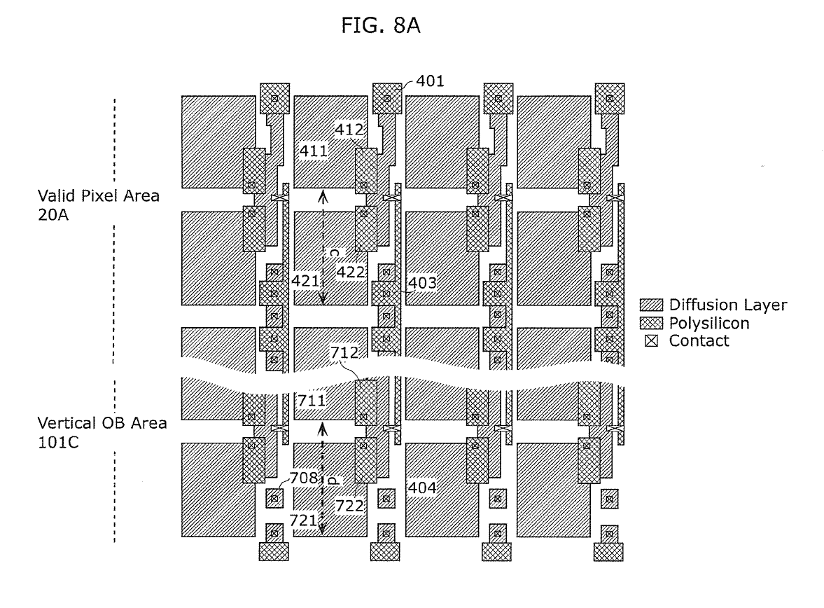

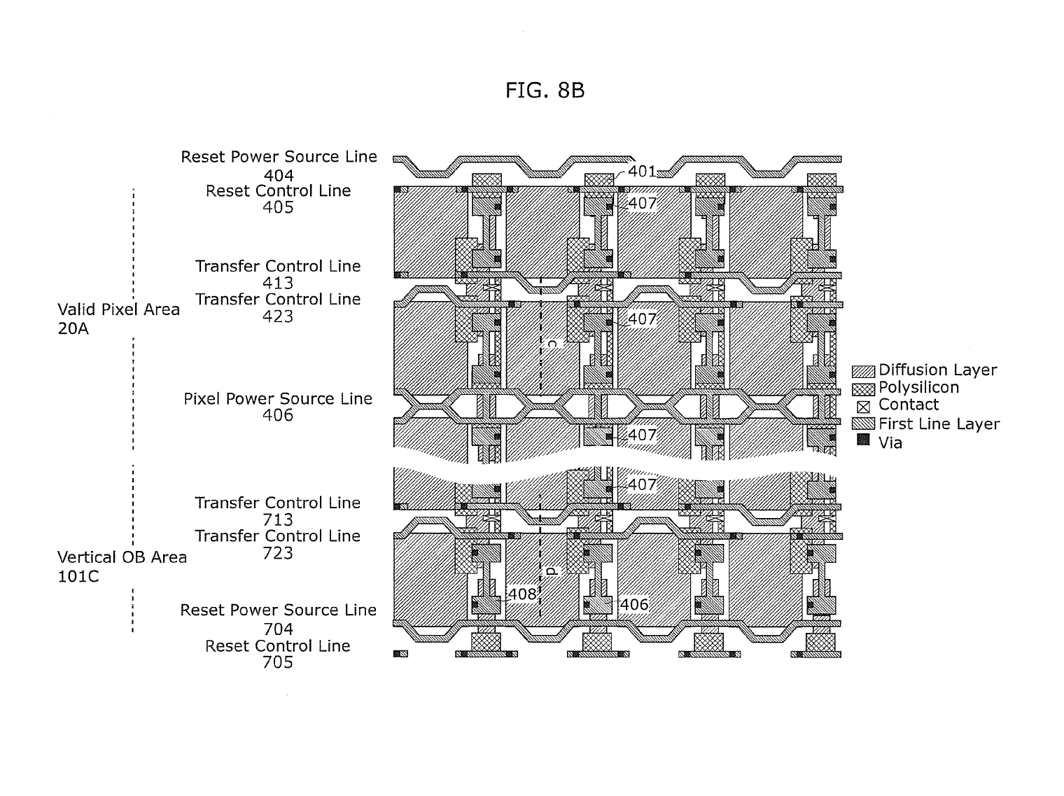

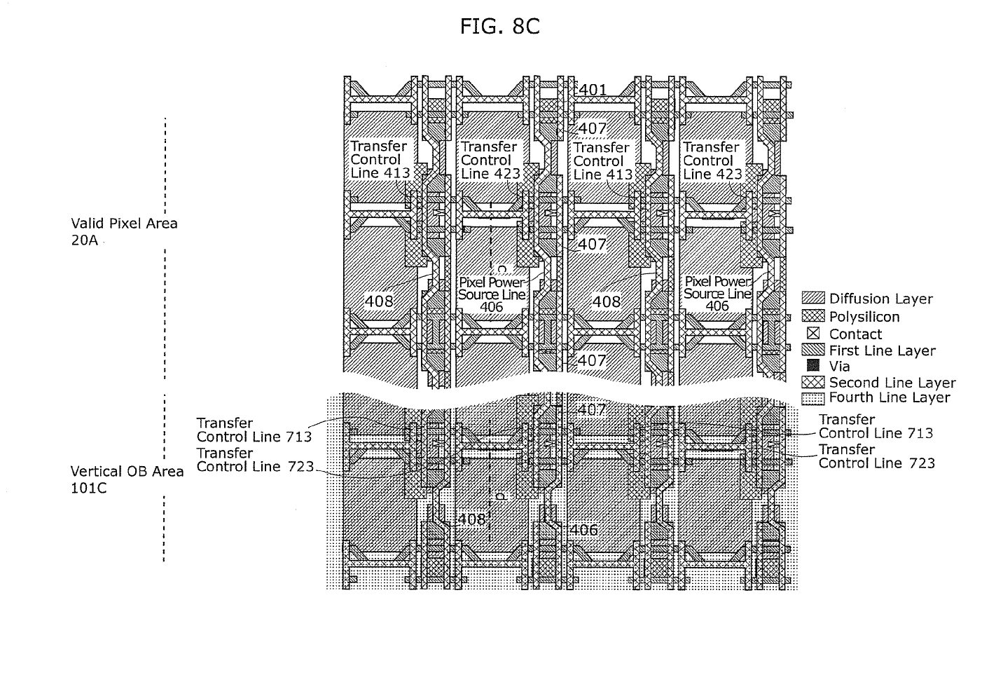

FIG. 8A is a planar layout diagram showing a silicon substrate that includes a diffusion layer, polysilicon, and contacts, according to Embodiment 2. FIG. 8B is a planar layout diagram showing: the silicon substrate; a first line layer above the silicon substrate; and vias connecting lines in the first line layer, according to Embodiment 2. FIG. 8C is a planar layout diagram showing: the silicon substrate; the first line layer and the vias all of which are above the silicon substrate; and a second line layer and a fourth line layer according to Embodiment 2.

Each of FIGS. 8A to 8C is a diagram showing a part of the pixel array according to the present embodiment. Each diagram shows the valid pixel area 20A in the upper part, and the vertical OB area 101C in the lower part of the diagram.

FIG. 8A shows a diffusion layer, polysilicon, and contacts, all of which are included in the silicon substrate. In each of the valid pixel area 20A and the vertical OB area 101C, photodiodes and transfer transistors are arranged. The photodiodes (PDs 411, 421, 711, 721, and the like in FIG. 8A) are provided at equal distances along a column direction. The transfer transistors (TGs 412, 422, 712, 722, and the like in FIG. 8A) are provided to correspond to the respective photodiodes. More specifically, each of the transfer transistors is provided to the upper right or the lower right of a corresponding photodiode.

FIG. 8A further shows an SF 403 and an RS 401. The SF 403 has a gate connected to a drain of the transfer transistor in the valid pixel. The RS 401 has a source that is also connected to the drain of the transfer transistor. Although not shown, the light-blocking pixel also has the same structure in which a drain of the transfer transistor is connected to both a gate of the SF 703 and a source of the RS 701.

FIG. 8B shows: the silicon substrate shown in FIG. 8A; the first line layer located above the silicon substrate; and vias connecting the first line layer to the second line layer. In the valid pixel area 20A and the vertical OB area 101C shown in FIG. 8B, the first line layer is located above the silicon substrate. The first line layer includes: transfer control lines 413, 423, 713, and 723, the pixel power source line 406, the reset power source lines 404 and 704, and the reset control lines 405 and 705.

FIG. 8C shows: the silicon substrate shown in FIG. 8B; the first line layer and the vias; the second line layer located above the first line layer and the vias; and a fourth line layer located above the second line layer. In the valid pixel area 20A and the vertical OB area 101C shown in FIG. 8C, the second line layer is provided above the first line layer. The second line layer includes: a signal line 407, transfer control lines 413, 423, 713, and 723, a pixel power source line 406, and a substrate-fixed potential line 408. In addition, in the vertical OB area 101C shown in FIG. 8C, the fourth line layer is provided above a third line layer. The fourth line layer covers the vertical OB area 101C to serve as a light-blocking film that blocks light incident on the photodiodes.

Here, in the peripheral circuit 20, the third line layer is provided between the second line layer and the fourth line layer. On the other hand, in the vertical OB area 101C, an interlayer insulating film is provided to a position corresponding to the third line layer. Moreover, the first to fourth line layers are arranged roughly at equal distances in a direction of stacking the layers.

In other words, a thickness of the interlayer insulating film between the second line layer and the fourth line layer in the vertical OB area 101C is equal to or more than twice as long as a distance between the first line layer and the second line layer.

The vertical OB area 101C further differs from the valid pixel area 20A in that the fourth line layer covers the entire vertical OB area 101C.

The above-described layout is characterized in that the reset power source line is provided in the first line layer, that the pixel power source line, the substrate-fixed potential line, the signal line, the transfer control line, and the reset control line are provided both in the first line layer and in the second line layer, and that the light-blocking film is provided in the fourth line layer.

Next, a cross-sectional surface structure is compared between the above-described pixel array according to the present embodiment and a conventional pixel array.

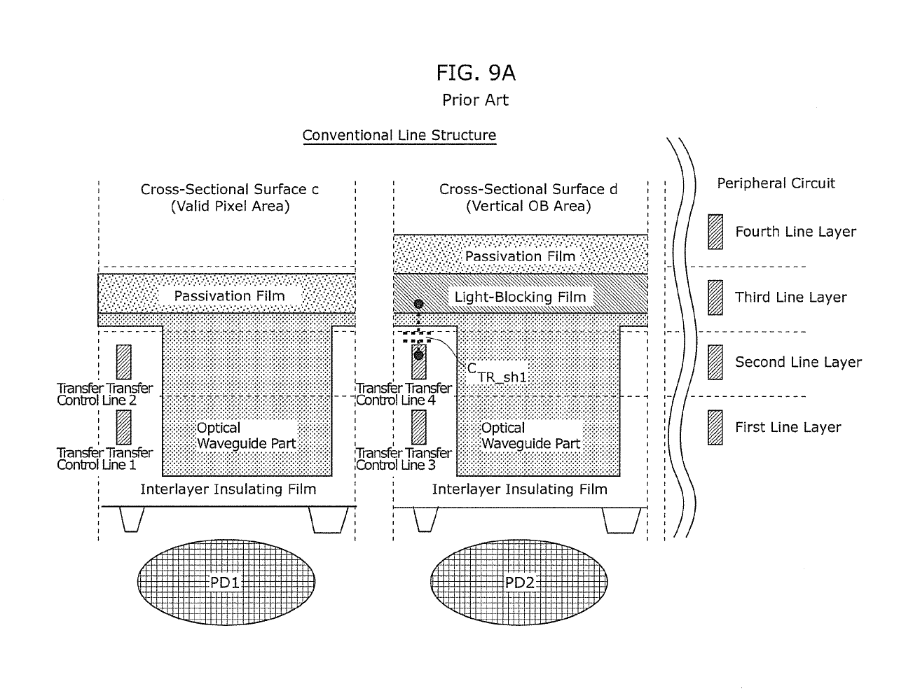

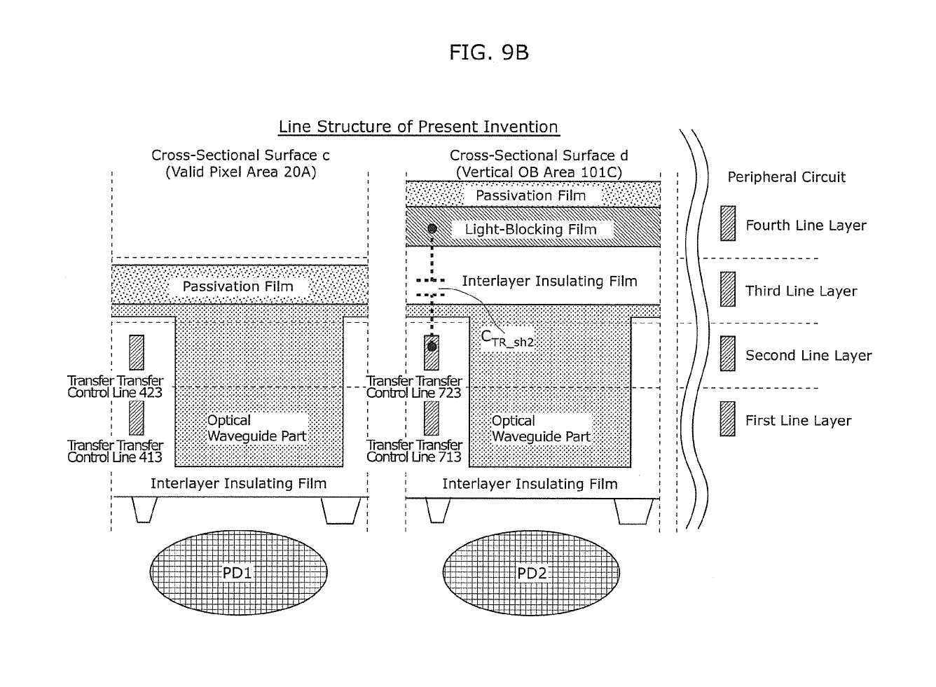

FIG. 9A is a cross-sectional view of pixels in the conventional solid-state imaging device. FIG. 9B is a cross-sectional view of pixels in the solid-state imaging device according to Embodiment 2. In both figures, a cross-sectional view on the left side shows a part taken along a broken line “c” in the valid pixel in the planar layout shown in FIGS. 8A to 8C. On the other hand, in both figures, a cross-sectional view on the right side shows a part taken along a broken line “d” in the light-blocking pixel in the planar layout shown in FIGS. 8A to 8C. In each of the valid pixel and the light-blocking pixel, a photodiode is provided in the silicon substrate. Above the photodiode, an optical waveguide part is provided. The optical waveguide part is made of a material having a high refractive index, such as SiN, to increase light-collection efficiency of the photodiode. In the first line layer and the second line layer, various lines are arranged at both sides of the optical waveguide part. The space between the various lines and the optical waveguide part is filled with an interlayer insulating film. Regarding the peripheral circuit, the first to fourth line layers are arranged roughly at equal distances in a direction of stacking the layers.

Regarding the valid pixel area, both in FIGS. 9A and 9B, the respective valid pixels have the same line layout. On the other hand, regarding the vertical OB area, the respective light-blocking pixels have different structures in FIGS. 9A and 9B. More specifically, in FIG. 9A showing the light-blocking pixel in the conventional solid-state imaging device, the light-blocking film is provided in the third line layer, while in FIG. 9B showing the light-blocking pixel in the solid-state imaging device of the present disclosure, the light-blocking film is provided in the fourth line layer.

In each of the structures, focusing attention to a transfer control line in the second line layer, the transfer control line in the light-blocking pixel has a parasitic capacitance C_{TR}_{_{—}}ₛₕ₁ or C_{TR}_{_{—}}ₛₕ₂, which a transfer control line in the valid pixel does not have. In order to reduce such a parasitic capacitance, in the light-blocking pixel according to the present disclosure in FIG. 9B, the region corresponding to the third line layer that is located above the second line layer as the top line layer in the valid pixel is not used as a line layer. However, in the light-blocking pixel according to the present disclosure in FIG. 9B, the region is filled with an interlayer insulating film, and a light-blocking film is further provided above the interlayer insulating film as the fourth line layer. This structure can significantly reduce the parasitic capacitance of the transfer control line with respect to the light-blocking film from C_{TR}_{_{—}}ₛₕ₁ to C_{TR}_{_{—}}ₛₕ₂. In viewing the cross-sectional structure from a position taken along the broken line “d” in FIGS. 8B and 8C, it seems that the transfer control line 713 is not in the top line layer in the light-blocking pixel, and that a change of the parasitic capacitance is small. However, in practice, since the transfer control line 713 is arranged alternately in the first line layer and in the second line layer in one pixel cycle, and the transfer control line 723 is also arranged alternately in the second line layer and in the first line layer in one pixel cycle. Therefore, the transfer control line 713 has the same problem as that in the transfer control line 723 regarding a parasitic capacitance occurred with respect to the light-blocking film. The above structure can solve the problem and offer the same effects for the transfer control lines 713 and 723.

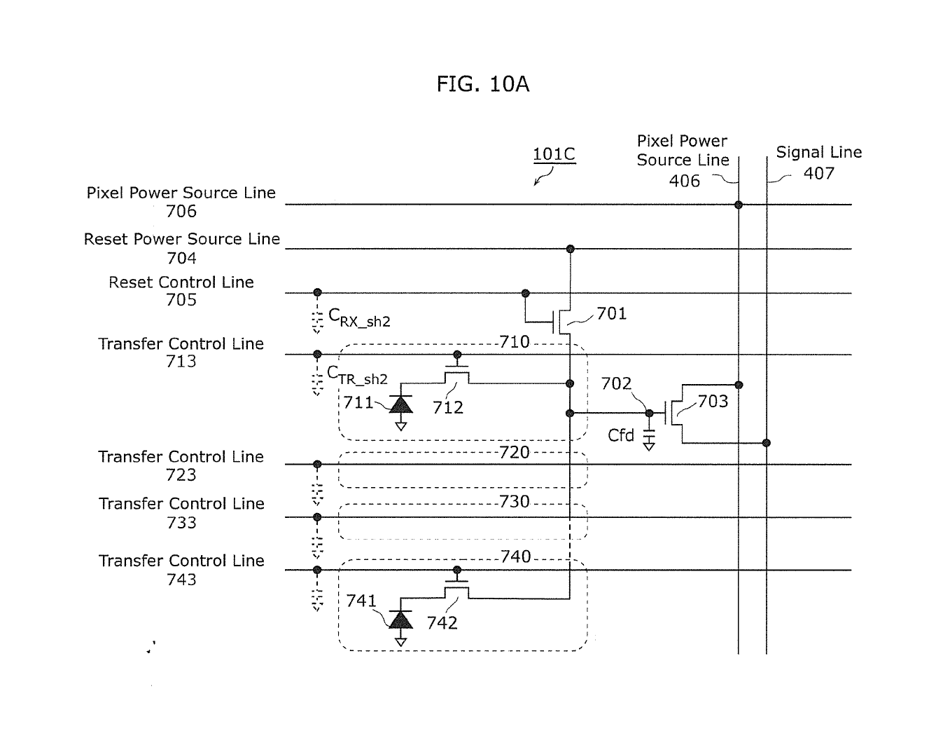

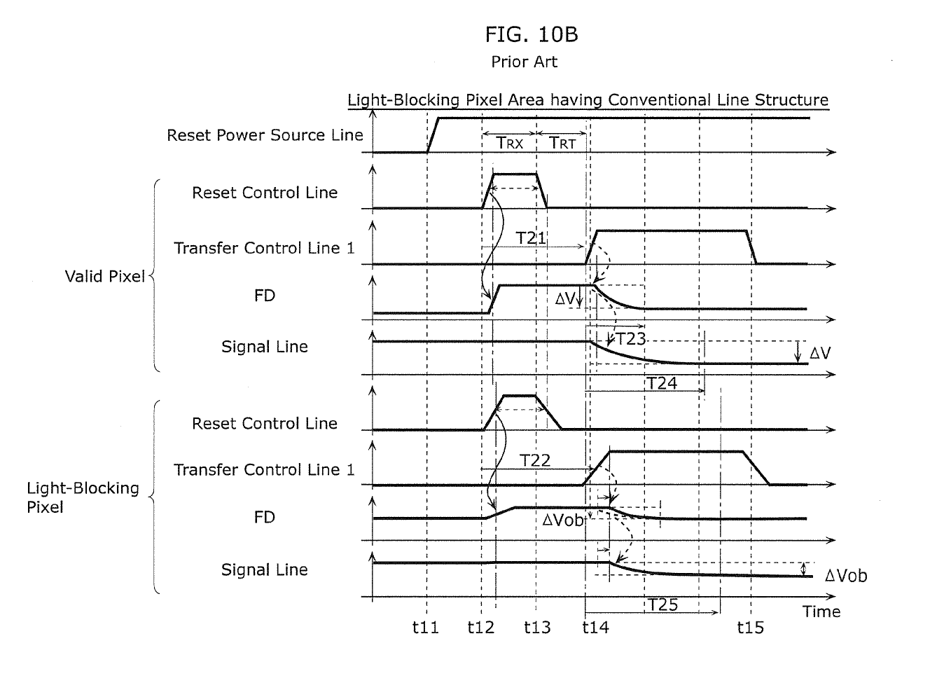

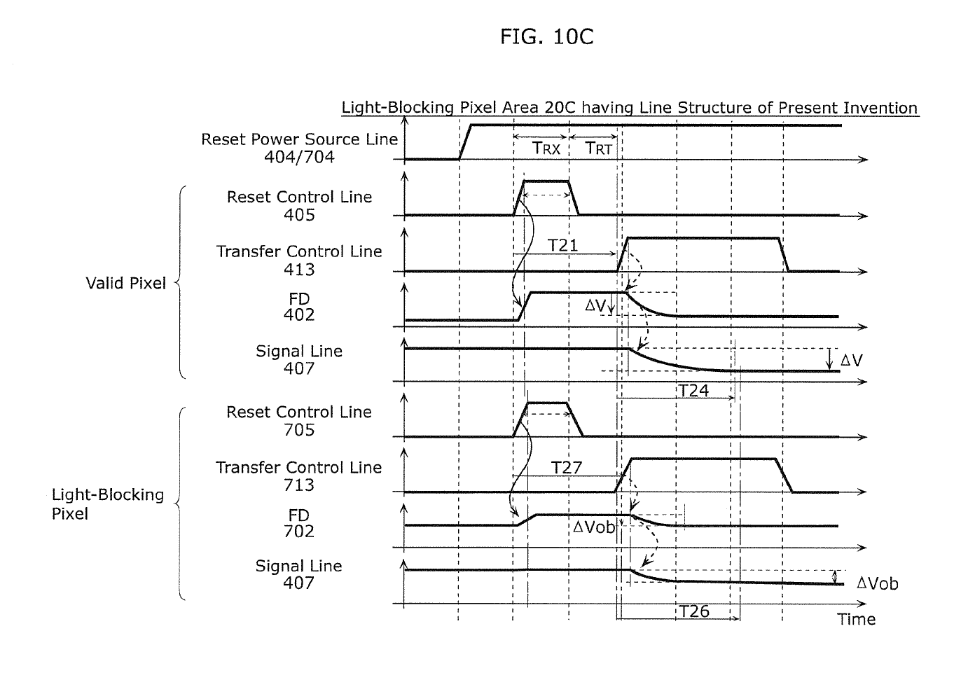

FIG. 10A is a circuit diagram showing a parasitic capacitance in a light-blocking pixel according to Embodiment 2. The parasitic capacitance is a difference between a layout of a light-blocking pixel and a layout of a valid pixel. The vertical OB area 101C has light-blocking pixels that include four light-blocking pixels 710, 720, 730, and 740 shown in FIG. 10A. The four light-blocking pixels share an RS 701, an FD 702, and an SF 703. In other words, all of the light-blocking pixels 710, 720, 730, and 740, the RS 701, the FD 702, and the SF 703 form a single pixel cell. In the vertical OB area 101C, a plurality of such pixel cells are arranged in a matrix.

The light-blocking pixel 710 includes a PD 711 and a TG 712. Likewise, each of the other light-blocking pixels also includes a photodiode and a transfer transistor. The SF 703 outputs signals to the signal line 407 according to a level of the FD 702. As described above, although the reference numerals assigned to the structural elements are different, the circuit structure is the same as that of the valid pixel shown in FIG. 7A. FIG. 10A shows that a parasitic capacitance C_{TR}_{_{—}}ₛₕ₂ occurs between the transfer control line 713 in the second line layer and the light-blocking film in the fourth line layer, and that that a parasitic capacitance C_{RX}_{_{—}}ₛₕ₂ occurs between the reset control line 705 in the first line layer and the light-blocking film in the fourth line layer.

FIG. 10B is a time chart in which a reading waveform of a valid pixel is compared to a reading waveform of a light-blocking pixel in the conventional solid-state imaging device. FIG. 10C is a time chart in which a reading waveform of a valid pixel is compared to a reading waveform of a light-blocking pixel in the solid-state imaging device according to Embodiment 2.

In both FIGS. 10B and 10C, the operations of the valid pixel are the same as described with reference to FIG. 7B. A potential level change ΔV of a FD is propagated as gain of roughly 1, and outputted from the pixel array. Here, when T24 represents a time duration required for the signal propagation via the signal line to the outside of the pixel array, T24 is longer than T23 due to influence of an RC time constant of the signal line.

Furthermore, in the conventional solid-state imaging device shown in FIG. 10B, a time duration from rising of a reset signal at time t12 to outputting a signal to a signal line is T21+T24 in a valid pixel, but T22+T25 in a light-blocking pixel, as seen in the figure. In short, the time duration required for the light-blocking pixel is longer than that for the valid pixel. The time difference is caused mainly by delay of rising of a transfer control line in the light-blocking pixel.

On the other hand, in the solid-state imaging device according to the present disclosure in FIG. 10C, the time difference is decreased. A time duration from rising of a reset signal at time t12 to outputting of a signal to a signal line is T27+T26 in a light-blocking pixel, which is shorter than T22+T25 in the light-blocking pixel in the conventional solid-state imaging device. Although only the time duration decrease is not enough to produce the significant effects as described in Embodiment 1, Embodiment 2 can offer more effects than that produced by the time duration decrease. The effects of Embodiment 2 are described below.

A light-blocking pixel and a valid pixel need to be controlled at the same regular timings over the whole pixel array. Therefore, (a) a time duration T_{RX} from rising of a reset signal propagated through a reset control line to falling of the reset signal and (b) a time duration T_{RT} from the falling of the reset signal to rising of a transfer control signal propagated through a transfer control line are basically the same between a valid pixel and a light-blocking pixel.

However, in the case of the conventional solid-state imaging device shown in FIG. 10B, a parasitic capacitance with respect to a light-blocking film affects the rising and/or the falling of the transfer control line and the reset control line in the light-blocking pixel. Therefore, the rising and/or the falling require a more time than that required for the transfer control line and the reset control line in the valid pixel area. This means that a stable period where the reset signal or the transfer control signal is stably kept at HIGH or LOW level is shortened.

As described previously, it is necessary to shorten a horizontal scanning period for speeding up. However, if the horizontal scanning period is shortened according to a time duration for reading from target valid pixels, the stable period is shortened. As a result, it is impossible to keep a pulse width necessary for resetting the pixels or for completing transfer.

However, in the case of the solid-state imaging device according to the present disclosure shown in FIG. 10C, even a light-blocking pixel can keep such a stable period where a control signal is stably kept at HIGH or LOW level. Therefore, it is possible to shorten the horizontal scanning period, and increase a frame rate to achieve a high speed.

The above structure enables high-speed reading of black level signals having an enough time margin from a light-blocking pixel in the vertical OB area 101C. As a result, it is possible to provide a solid-state imaging device capable of obtaining, at a high speed, image with correct black reference and with a small amount of noises even on the conditions where a light amount is small.

It is preferable that the light-blocking film provided in the fourth line layer in the vertical OB area 101C is made of aluminium. If the light-blocking film comprises aluminium, the light-blocking performance is dramatically improved. As a result, one layer is enough to block light. It is also possible that the light-blocking film is made of copper. In this case, the light-blocking performance can be kept, if a color filter provided above the valid pixels is a black filter having high light-blocking performance.

It is further possible that, in order to decrease a difference between a load on a signal line in a valid pixel and a load on a signal line in a light-blocking pixel, the interlayer insulating film between the fourth line layer and the second line layer in the vertical OB area 101C may comprise a so-called Low-k material having a low permittivity. Thereby, it is possible to decrease the value of the parasitic capacitance between the light-blocking film in the fourth line layer and the line in the second line layer.

It should be noted that it has been described in the present embodiment that each of the vertical OB area and the peripheral circuit area has four line layers, but the present invention is not limited to the structure. More specifically, the present invention may be any solid-state imaging device that when (i) the valid pixel area has N line layers (where N is a natural number), (ii) the vertical OB area has M line layers (where M is a natural number), (iii) the peripheral circuit area has L line layers (where L is a natural number), (iv) the valid pixel area, the vertical OB area, and the peripheral circuit area share line layers up to an N-th line layer from a surface of the semiconductor substrate, and (v) N<M≦L, a light-blocking line layer among the line layers blocks light incident on photoelectric conversion elements in the vertical OB area, and an interlayer insulating film is filled between the light-blocking line layer and the N-th line layer, the light-blocking line layer being one of an (N+2)th line layer and a line layer higher than the (N+2)th line layer. Such a solid-state imaging device can offer the same effects.

Although the solid-state imaging device according to the present disclosure has been described with reference to the embodiments as above, the solid-state imaging device according to the present disclosure is not limited to these embodiments. Those skilled in the art will be readily appreciated that various modifications and combinations of the structural elements are possible in the exemplary embodiments without departing from the scope of the present invention. Such modifications and combinations are also embodiments of the present disclosure. For example, a camera in which the solid-state imaging device according to the present disclosure is embedded is also included in the present invention.

It should be noted that it has been described in Embodiments 1 and 2 that the pixel structure does include a selection transistor, but it is also possible to include a selection transistor in the pixel structure. In this case, a pixel election control line used for controlling the selection transistor is provided in the top line layer of a valid pixel. It is thereby possible that a valid pixel and a light-blocking pixel have the same reading characteristics in the same manner as described in detail for the signal line and the transfer control line in Embodiments 1 and 2. As a result, the same effects, such as image quality improvement and high-speed reading, can be offered.

It should also be noted in Embodiments 1 and 2 that the fact that a driving time duration for driving a pixel power source line or a reset control line varies depending on a load is not described for the sake of convenience in explaining the time charts. However, it is sure that a difference between a load on a valid pixel and a load on a light-blocking pixel also occurs if the pixel power source line or the reset control line is provided in the top line layer of the valid pixel and that the difference results in a difference between reading characteristics of valid pixel and reading characteristics of the light-blocking pixel. Therefore, the present invention is not limited to the structure in which only a transfer control line and a signal line are located in the top line layer of the valid pixel. It is also possible that one of (a) all of control signal lines, (b) all of power source lines, and (b) a reading signal line, which is used to control driving of pixels, is located in the top surface.

It should also be noted that it is preferable that, in order to prevent deterioration of light-blocking performance for blocking light incident obliquely from the valid pixel area or the invalid pixel area to the light-blocking pixel, a light-blocking side wall is provided at a boundary part between the valid pixel area and the light-blocking pixel area, at least between (a) an N-th line layer counted from the surface of the semiconductor substrate and (b) a line layer that blocks light incident on the photodiode in the light-blocking pixel area.

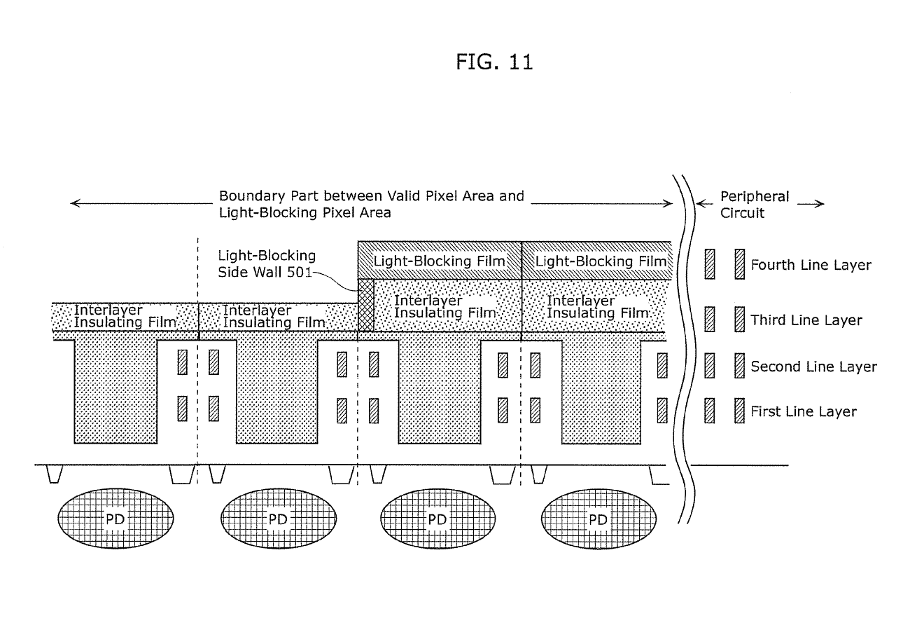

FIG. 11 is a cross-sectional view of the boundary part between the valid pixel area and the light-blocking pixel area in the solid-state imaging device according to a variation of the above embodiments. As shown in FIG. 11, at the boundary part between the valid pixel area and the light-blocking pixel area in the solid-state imaging device according to the present disclosure, a light-blocking side wall 501 is provided between (a) an N-th line layer and (b) an (N+2)th line layer in which a light-blocking film is formed. The light-blocking side wall 501 is preferably made mainly of a heavy metal or a high melting point material which is used for the vias connecting the line layers. This structure can dramatically increase light-blocking performance. As a result, it is possible to offer enough light-blocking performance, even if the number of line layers serving as a light-blocking film is small.

Furthermore, in order to prevent deterioration of light-blocking performance on light incident obliquely to the light-blocking pixel area, it is also possible to increase an invalid pixel area so that light leaked from the valid pixel area does not practically reach the light-blocking pixel area. The method is included in the present invention.

It should be noted that it has been described in the present embodiments that the row scanning circuit sequentially selects rows of pixels in the pixel array 10 one by one. However, in order to perform the reading at a double or more speed, or in order to add signals read from a plurality of rows together, it is also possible to select two or more rows at the same time.

It should also be noted that it has described that the line layers are arranged roughly at equal distances, but it is not necessary that the respective line layers have the same thickness or that the interlayer insulating film has the same thickness. It should also be noted that it is not necessary that the lines and the interlayer insulating film are made of the same material.

### INDUSTRIAL APPLICABILITY

The solid-state imaging device according to the present invention is applicable to digital still cameras, digital camcorders, mobile telephones with camera function, and the like, and therefore has industrial applicability.

1. A solid-state imaging device in which a plurality of pixel cells are arrayed in a matrix in or on a semiconductor substrate, the pixel cells each including a photoelectric conversion element and a transistor connected to the photoelectric conversion element, the solid-state imaging device comprising:
a valid pixel area including valid pixel cells from each of which an image signal corresponding to incident light is outputted, the valid pixel cells being included in the pixel cells;
a light-blocking pixel area peripheral to the valid pixel area and including light-blocking pixel cells from each of which a black level signal independent of the incident light that is blocked is outputted, the light-blocking pixel cells being included in the pixel cells; and
a peripheral circuit area peripheral to the valid pixel area and the light-blocking pixel area, the peripheral circuit area including a peripheral circuit that drives the pixel cells and performs signal processing,
wherein, when (i) the valid pixel area has N line layers (where N is a natural number), (ii) the light-blocking pixel area has M line layers (where M is a natural number), (iii) the peripheral circuit area has L line layers (where L is a natural number), (iv) the valid pixel area, the light-blocking pixel area, and the peripheral circuit area share line layers up to an N-th line layer from a surface of the semiconductor substrate, and (v) N<M≦L, a light-blocking line layer among the line layers blocks light incident on photoelectric conversion elements in the light-blocking pixel area, and an interlayer insulating film is filled between the light-blocking line layer and the N-th line layer, the light-blocking line layer being one of an (N+2)th line layer and a line layer higher than the (N+2)th line layer.

2. The solid-state imaging device according to claim 1,
wherein N is 2,
the peripheral circuit area has lines in all of a first line layer, a second line layer, a third line layer, and a fourth line layer from the surface of the semiconductor substrate,
the valid pixel area has lines in the first line layer and the second line layer, and
the light-blocking pixel area has lines in the first line layer, the second line layer, and the fourth line layer.

3. The solid-state imaging device according to claim 1,
wherein the light-blocking line layer includes a light-blocking film comprising aluminium.

4. The solid-state imaging device according to claim 1,
wherein a light-blocking side wall is provided at least between the N-th line layer and the light-blocking line layer at a boundary between the valid pixel area and the light-blocking pixel area, the light-blocking side wall blocking light and comprising a heavy metal used in a via connecting the line layers.

5. The solid-state imaging device according to claim 1, further comprising
signal lines each provided at least for a corresponding one of columns of the pixels cells, the signal lines being used to read pixel signals generated in the valid pixel cells to outside of the valid pixel area, and used to read black level signals generated in the light-blocking pixel cells to outside of the light-blocking pixel area,
wherein the light-blocking pixel area is provided along a direction of arranging rows of the valid pixel cells, and
the signal lines are provided in the N-th line layer.

6. The solid-state imaging device according to claim 1, further comprising
transfer control lines each provided at least for a corresponding one of rows of the pixel cells, the transfer control lines each being used to control transfer of charges generated in the photoelectric conversion element to a charge accumulation unit,
wherein the light-blocking pixel area is provided along a direction of arranging columns of the valid pixel cells, and
the transfer control lines are provided at least in the N-th line layer.

7. The solid-state imaging device according to claim 1,
wherein the interlayer insulating film comprises a Low-k material.

8. The solid-state imaging device according to claim 1,
wherein the interlayer insulating film has a thickness that is at least twice as long as a distance between an (N−1)th line layer and the N-th line layer from the surface of the semiconductor substrate.
